(19) United States
(12) Patent Application Publication
(10) Pub. No.: US 2014/0151680 A1
(43) Pub. Date: Jun. 5, 2014

(54) POLYMER COMPOUND AND ORGANIC TRANSISTOR USING SAME

(71) Applicants: Hiroki Terai, Tsukuba-shi (JP); Shinya Ito, Tsukuba-shi (JP); Tomoya Kashiki, Tsukuba-shi (JP)

(72) Inventors: Hiroki Terai, Tsukuba-shi (JP); Shinya Ito, Tsukuba-shi (JP); Tomoya Kashiki, Tsukuba-shi (JP)

(73) Assignee: SUMITOMO CHEMICAL COMPANY, LIMITED, Chuo-ku, Tokyo (JP)

(21) Appl. No.: 14/235,377

(22) PCT Filed: Jul. 26, 2012
(86) PCT No.: PCT/JP2012/069017

§ 371 Date: Jan. 27, 2014

(30) Foreign Application Priority Data
Jul. 29, 2011 (JP) 2011-166836

(51) Int. Cl. H01L 51/00; H01L 51/05

(52) U.S. Cl. CPC H01L 51/0036; H01L 51/0541; H01L 51/0545
USPC 257/40; 526/256; 526/257

(57) ABSTRACT

A polymer compound comprising a structural unit represented by the formula:

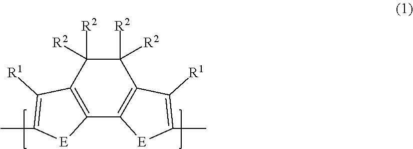

wherein E represents —O—, —S— or —Se—; R¹ represents a hydrogen atom, an alkyl group, an alkoxy group, an alkylthio group, an aryl group, a heteroaryl group or a halogen atom; and R² represents a hydrogen atom, an alkyl group, an aryl group, a heteroaryl group or a halogen atom, or two R²s are linked to form a ring, and a structural unit which is different from the structural unit represented by the formula (1) and is represented by the formula:

Ar¹ (2)

wherein Ar¹ represents a divalent aromatic group, a group represented by —CR³═CR³— or a group represented by —C≡C—, wherein R³ represents a hydrogen atom, an alkyl group, an aryl group, a heteroaryl group or a cyano group.

### TECHNICAL FIELD

The present invention relates to a polymer compound and an organic transistor using the same.

### BACKGROUND ART

Organic semiconductor materials are extensively researched and developed because when they are used as constituent materials of organic transistors, weight reduction of devices, reduction of production costs and lowering of production temperature are expected in comparison with inorganic transistors using conventional inorganic semiconductor materials.

Among organic semiconductor materials, those excellent in chemical stability and soluble in a solvent can be easily and inexpensively formed into a thin film by a coating method, thus contributing in particular to reduction of production costs and lowering of production temperature of organic transistors. Therefore, particularly polymer compounds, with which materials that have a high degree of freedom in molecular design and are soluble in a solvent are easily provided, are attracting attention.

However, organic transistors have the problem that electric field effect mobility is low in comparison with inorganic transistors. Electric field effect mobility of the organic transistor depends on electric field effect mobility of an organic semiconductor material contained in an active layer. Therefore, for enhancing electric field effect mobility of the organic transistor, organic semiconductor materials having high electric charge mobility are desired.

The organic semiconductor material is generally a group of compounds having a π-conjugated system in the molecule, with electric charges moving through the π-conjugated system. Therefore, by selecting, as structural units, various kinds of fused ring compounds having π-conjugated bonds, and combining the fused ring compounds to optimize the arrangement of π-conjugated bonds in the organic semiconductor material, electric charge mobility of the organic semiconductor material can be enhanced.

For example, Patent Document 1 proposes the following polymer compound as an organic semiconductor material to be used for an organic transistor.

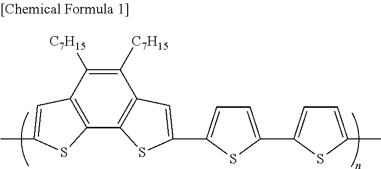

### BACKGROUND ART DOCUMENT

### Patent Document

Patent Document 1: Japanese Patent Laid-open Publication No. 2007-269775

### SUMMARY OF THE INVENTION

### Problem to be Solved by the Invention

However, organic transistors including the above-mentioned polymer compound in an active layer have the problem that electric field effect mobility is not sufficient.

An object of the present invention is to provide a polymer compound which makes electric field effect mobility sufficiently high when used for an active layer of an organic transistor.

### Means for Solving the Problem

That is, the present invention provides a polymer compound comprising a structural unit represented by the formula:

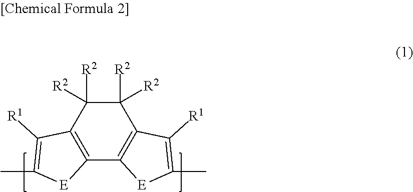

wherein each E independently represents —O—, —S— or —Se—; each R¹ independently represents a hydrogen atom, an alkyl group which optionally has a substituent, an alkoxy group which optionally has a substituent, an alkylthio group which optionally has a substituent, an aryl group, a heteroaryl group or a halogen atom; and each R² independently represents a hydrogen atom, an alkyl group which optionally has a substituent, an aryl group, a heteroaryl group or a halogen atom, or two R²s are linked to form a ring and each of the other R²s independently represents a hydrogen atom, an alkyl group which optionally has a substituent, an aryl group, a heteroaryl group or a halogen atom, and a structural unit which is different from the structural unit represented by the formula (1) and is represented by the formula:

[Chemical Formula 3]

Ar¹ (2)

wherein Ar¹ represents a divalent aromatic group, a group represented by —CR³═CR³— or a group represented by wherein each R³ independently represents a hydrogen atom, an alkyl group which optionally has a substituent, an aryl group, a heteroaryl group or a cyano group.

The present invention also provides an organic semiconductor material comprising the polymer compound.

The present invention also provides an organic semiconductor device comprising an organic layer including the organic semiconductor material.

The present invention also provides a method for producing a compound represented by the formula (8), wherein the method comprises a step of reacting a compound represented by the formula (7) with a metal hydride:

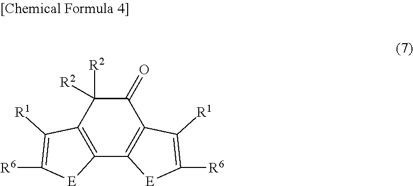

wherein each E independently represents —O—, —S— or —Se—; each R¹ independently represents a hydrogen atom, an alkyl group which optionally has a substituent, an alkoxy group which optionally has a substituent, an alkylthio group which optionally has a substituent, an aryl group, a heteroaryl group or a halogen atom; each R² independently represents a hydrogen atom, an alkyl group which optionally has a substituent, an aryl group, a heteroaryl group or a halogen atom, or two R²s are linked to form a ring and each of the other R²s independently represents a hydrogen atom, an alkyl group which optionally has a substituent, an aryl group, a heteroaryl group or a halogen atom; and each R⁶ independently represents a hydrogen atom, an alkyl group which optionally has a substituent, an alkoxy group which optionally has a substituent, an alkylthio group which optionally has a substituent, an aryl group, a heteroaryl group or a halogen atom;

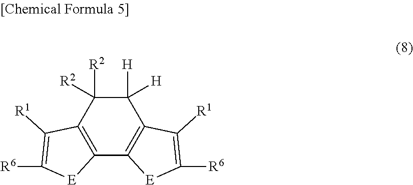

wherein E, R¹, R² and R⁶ have the same meanings as those described above.

### Effects of the Invention

An organic transistor including a polymer compound of the present invention in an active layer shows high electric field effect mobility.

### BRIEF DESCRIPTION OF THE DRAWINGS

FIG. 1 A schematic sectional view showing one example of the organic transistor of the present invention.

FIG. 2 A schematic sectional view showing another example of the organic transistor of the present invention.

FIG. 3 A schematic sectional view showing another example of the organic transistor of the present invention.

FIG. 4 A schematic sectional view showing another example of the organic transistor of the present invention.

FIG. 5 A schematic sectional view showing another example of the organic transistor of the present invention.

FIG. 6 A schematic sectional view showing another example of the organic transistor of the present invention.

FIG. 7 A schematic sectional view showing another example of the organic transistor of the present invention.

FIG. 8 A schematic sectional view showing another example of the organic transistor of the present invention.

FIG. 9 A schematic sectional view showing another example of the organic transistor of the present invention.

### EMBODIMENTS FOR CARRYING OUT THE INVENTION

Preferred embodiments of the present invention will be described in detail below with reference to the drawings as necessary. In the description of the drawings, the same elements are given the same reference numerals, and duplicated explanations are omitted.

In this description, a “structural unit” means a unit structure one or more of which exist in a polymer compound. Preferably, the “structural unit” is contained in a polymer compound as a “repeating unit” (i.e. a unit structure two or more of which exist in a polymer compound).

<Polymer Compound>

(First Structural Unit)

The polymer compound of the present invention includes a structural unit represented by the formula (1) (hereinafter sometimes referred to as a “first structural unit”). Either only one kind or two or more kinds of the first structural unit may be included in the polymer compound.

In the formula (1), each E independently represents —O—, —S— or —Se—.

E is preferably —S— from the viewpoint of ease of synthesizing a monomer that serves as a raw material of the polymer compound of the present invention.

In the formula (1), each R¹ independently represents a hydrogen atom, an alkyl group which optionally has a substituent, an alkoxy group which optionally has a substituent, an alkylthio group which optionally has a substituent, an aryl group, a heteroaryl group or a halogen atom, or two R²s are linked to form a ring and the other R²s independently represent a hydrogen atom, an alkyl group which optionally has a substituent, an aryl group, a heteroaryl group or a halogen atom.

Here, the alkyl group may be either linear or branched, or may be a cycloalkyl group. The number of the carbon atoms of the alkyl group is usually 1 to 60, preferably 1 to 20. Among alkyl groups, linear alkyl groups and branched alkyl groups are preferable, and linear alkyl groups are more preferable.

Specific examples of the alkyl group include linear alkyl groups such as a methyl group, an ethyl group, a n-propyl group, a n-butyl group, a n-hexyl group, a n-octyl group, a n-dodecyl group, and a n-octadecyl group; branched alkyl groups such as an isopropyl group, an isobutyl group, a sec-butyl group, a tert-butyl group, a 2-ethylhexyl group, and a 3,7-dimethyloctyl group; and cycloalkyl groups such as a cyclopentyl group and a cyclohexyl group.

The alkyl group optionally has a substituent, and examples of the substituent which the alkyl group optionally has include an alkoxy group, an aryl group, and a halogen atom. Specific examples of the alkyl group having a substituent include a methoxyethyl group, a benzyl group, a trifluoromethyl group, and a perfluorohexyl group.

The alkoxy group optionally has a substituent, and the number of the carbon atoms of the alkoxy group except the substituent is usually 1 to 20. The alkoxy group may be either linear or branched, or may be a cycloalkoxy group.

Specific examples of the alkoxy group include an n-butyloxy group, a n-hexyloxy group, a 2-ethylhexyloxy group, a 3,7-dimethyloctyloxy group, and a n-dodecyloxy group.

Examples of the substituent which the alkoxy group optionally has include an aryl group and a halogen atom.

Among alkoxy groups, linear alkyloxy groups such as a n-butyloxy group, a n-hexyloxy group, and a n-dodecyloxy group are preferable.

The alkylthio group optionally has a substituent, and the number of carbon atoms of the alkylthio group except the substituent is usually 1 to 20. The alkylthio group may be either linear or branched, or may be a cycloalkylthio group.

Specific examples of the alkylthio group include a n-butylthio group, a n-hexylthio group, a 2-ethylhexylthio group, a 3,7-dimethyloctylthio group, and a n-dodecylthio group.

Examples of the substituent which the alkylthio group optionally has include an aryl group and a halogen atom.

Among alkylthio groups, linear alkylthio groups such as a n-butylthio group, a n-hexylthio group, and a n-dodecylthio group are preferable.

The aryl group is an atomic group resulting from the removal of one hydrogen atom directly attached to an aromatic ring from an aromatic hydrocarbon compound which optionally has a substituent, and the aryl group includes a group having a benzene ring, a group having a fused ring, or a group in which two or more independent aromatic rings or fused rings are directly linked. The number of the carbon atoms of the aryl group is usually 6 to 60, preferably 6 to 20. Examples of the aryl group include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 4-phenylphenyl group, and a 4-hexylphenyl group.

Examples of the substituent which the aromatic hydrocarbon compound optionally has include an alkoxy group, an alkylthio group, a heteroaryl group, and a halogen atom. Examples of the aryl group including the above-mentioned groups include a 3,5-dimethoxyphenyl group and a pentafluorophenyl group. When the aromatic hydrocarbon compound has a substituent, the substituent is preferably an alkyl group.

The heteroaryl group is an atomic group resulting from the removal of one hydrogen atom directly attached to an aromatic ring from an aromatic heterocyclic compound which optionally has a substituent, and the heteroaryl group includes a group having a fused ring, or a group in which two or more independent heterocyclic aromatic rings or fused rings are directly linked. The number of the carbon atoms of the heteroaryl group is usually 2 to 60, preferably 3 to 20. Examples of the heteroaryl group include a 2-furyl group, a 3-furyl group, a 2-thienyl group, a 3-thienyl group, a 2-pyrrolyl group, a 3-pyrrolyl group, a 2-oxazolyl group, a 2-thiazolyl group, a 2-imidazolyl group, a 2-pyridyl group, a 3-pyridyl group, a 4-pyridyl group, a 2-benzofuryl group, a 2-benzothienyl group, and a 2-thienothienyl group.

Examples of the substituent which the heterocyclic compound optionally has include an alkyl group, an alkoxy group, an alkylthio group, an aryl group, and a halogen atom. Examples of the heteroaryl group including these groups include a 5-octyl-2-thienyl group and a 5-phenyl-2-furyl group. When the heterocyclic compound has a substituent, the substituent is preferably an alkyl group.

Examples of the halogen atom include a fluorine atom, a chlorine atom, a bromine atom and an iodine atom.

R¹ is preferably a hydrogen atom from the viewpoint of ease of synthesizing a monomer that serves as a raw material of the polymer compound of the present invention.

Each R² independently represents a hydrogen atom, an alkyl group which optionally has a substituent, an aryl group, a heteroaryl group or a halogen atom, or two R²s are linked to form a ring and each of the other R²s independently represents a hydrogen atom, an alkyl group which optionally has a substituent, an aryl group, a heteroaryl group or a halogen atom.

The definition and specific examples of the alkyl group, aryl group, heteroaryl group or halogen atom represented by R² are the same as the foregoing definition and specific examples of the alkyl group, aryl group, heteroaryl group or halogen atom represented by R¹.

When two R²s are linked to form a ring, examples of the ring include a cyclopentane ring which optionally has a substituent, a cyclohexane ring which optionally has a substituent, and a cycloheptane ring which optionally has a substituent.

R² is preferably a hydrogen atom or an alkyl group which optionally has a substituent. A plurality of R²s are preferably the same alkyl group.

Examples of the first structural unit include structural units represented by the formulae (1-1) to (1-12). Among them, structural units represented by the formula (1-1) are preferable from the viewpoint of ease of synthesizing a monomer that serves as a raw material of the polymer compound of the present invention.

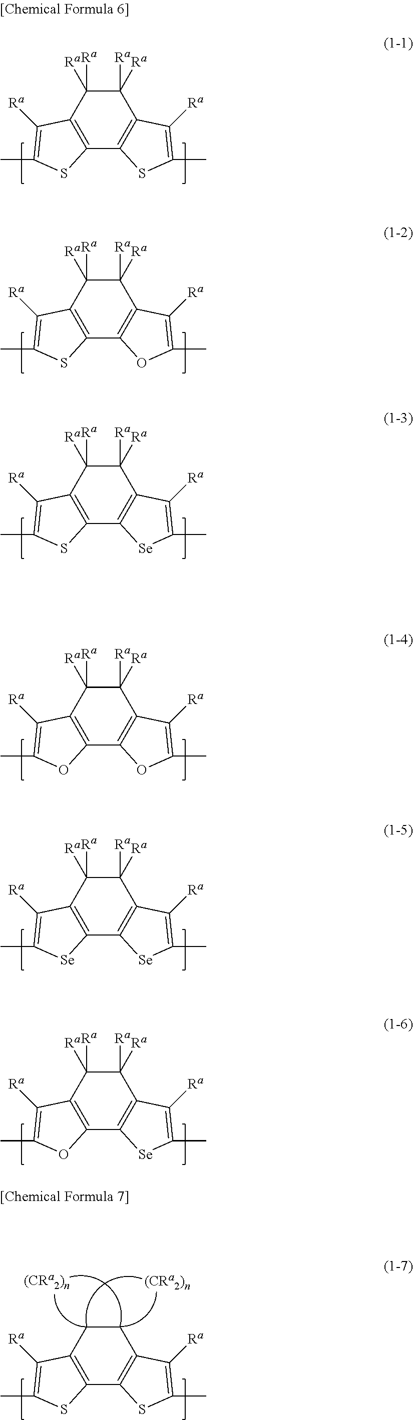

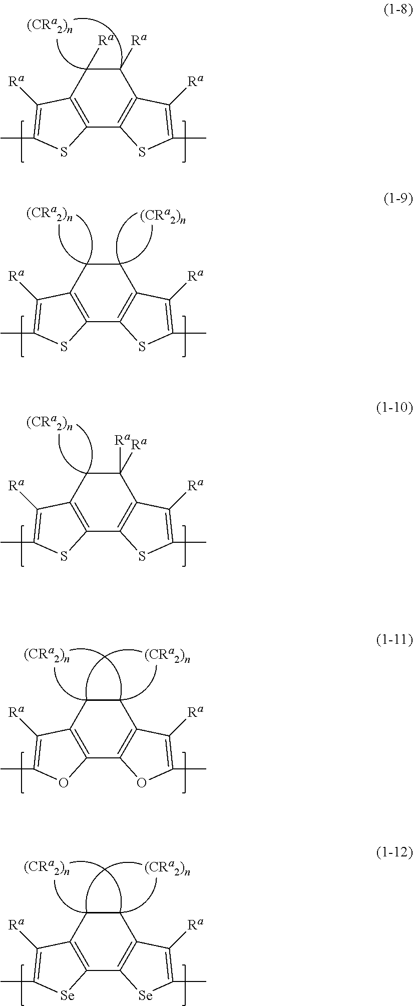

In the structural unites, each R^{a} independently represents a hydrogen atom, an alkyl group which optionally has a substituent, an alkoxy group which optionally has a substituent, an alkylthio group which optionally has a substituent, an aryl group, a heteroaryl group or a halogen atom; and each n independently represents an integer of 1 to 20.

The definition and specific examples of the alkyl group, alkoxy group, alkylthio group, aryl group or heteroaryl group represented by R^{a} are the same as the foregoing definition and specific examples of the alkyl group, alkoxy group, alkylthio group, aryl group or heteroaryl group represented by R¹.

The first structural unit includes a structure in which bichalcogenophenes are bridged at positions 3 and 3′ with ethylene. The structure is expected to act in favor of electric field effect mobility because the structure has an effect to fix a dihedral angle between bichalcogenophenes.

(Second Structural Unit)

The polymer compound of the present invention includes a structural unit represented by the formula (2) (hereinafter sometimes referred to as a “second structural unit”). Either only one kind or two or more kinds of the second structural unit may be included in the polymer compound.

In the formula, Ar¹ represents a divalent aromatic group, a group represented by —CR³═CR³— or a group represented by —C≡C—; and each R³ independently represents a hydrogen atom, an alkyl group which optionally has a substituent, an aryl group, a heteroaryl group or a cyano group.

The divalent aromatic group is an atomic group resulting from the removal of two hydrogen atoms directly attached to carbon atoms forming an aromatic ring from an aromatic compound which optionally has a substituent, and the divalent aromatic group includes a group having a benzene ring, a group having a fused ring, or a group in which two or more independent aromatic rings or fused rings are directly linked. Examples of the substituent include an alkyl group, an alkoxy group, an alkylthio group, an aryl group, a heteroaryl group and a halogen atom. The definition and specific examples of the alkyl group, alkoxy group, alkylthio group, aryl group, heteroaryl group and halogen atom are the same as the definition and specific examples of the alkyl group, alkoxy group, alkylthio group, aryl group, heteroaryl group and halogen atom represented by R¹. Examples of the divalent aromatic group include a phenylene group, a naphthalenediyl group, an anthracenediyl group, a phenanthrenediyl group, a tetracenediyl group, a pyrenediyl group, a pentacenediyl group, a perylenediyl group, a fluorenediyl group, an oxadiazolediyl group, a thiadiazolediyl group, an oxazolediyl group, a thiazolediyl group, a thiophenediyl group, a bithiophenediyl group, a terthiophenediyl group, a quaterthiophenediyl group, a pyrrolediyl group, a furandiyl group, a selenophenediyl group, a pyridinediyl group, a pyrazinediyl group, a pyrimidinediyl group, a triazinediyl group, a benzothiophenediyl group, a benzopyrrolediyl group, a benzofurandiyl group, a quinolinediyl group, an isoquinolinediyl group, a thienothiophenediyl group, a benzodithiophenediyl group, a benzothiadiazolediyl group, and a quinoxalinediyl group.

The definition and specific examples of the alkyl group, aryl group and heteroaryl group represented by R³ are the same as the foregoing definition and specific examples of the alkyl group, aryl group and heteroaryl group represented by R¹.

For enhancing the electric field effect mobility of the polymer compound, Ar¹ is preferably a divalent aromatic group, more preferably a divalent aromatic group containing an aromatic ring including a hetero atom, further preferably structural units represented by the formulae (3-1) to (3-15).

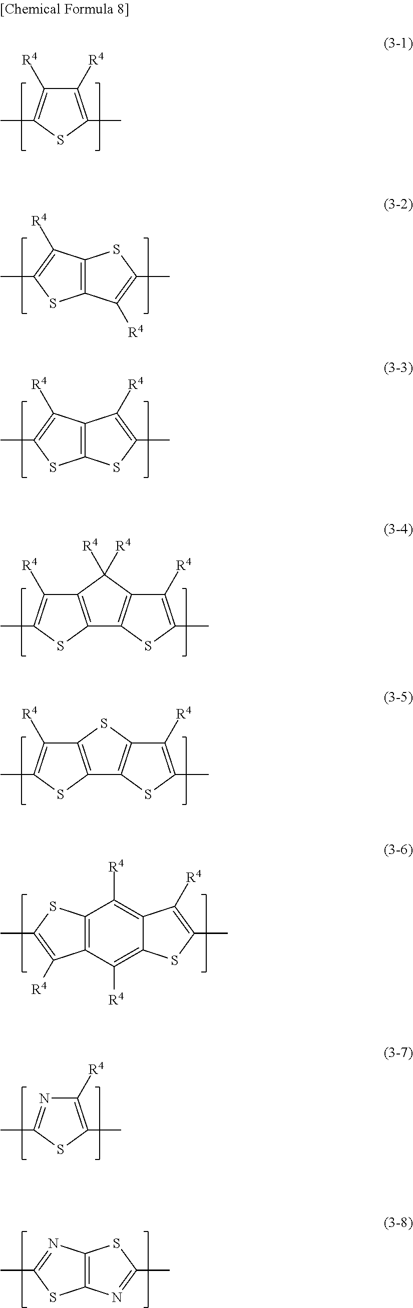

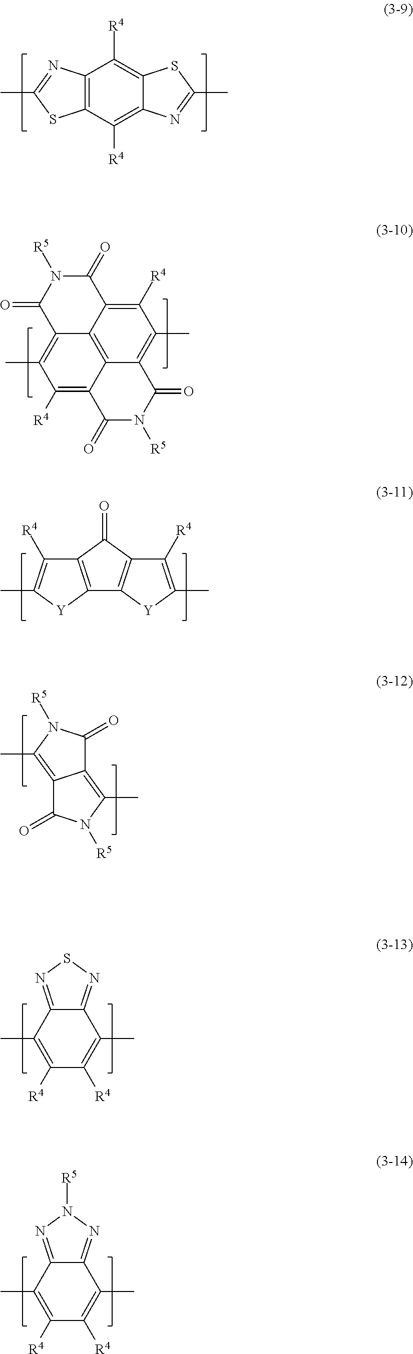

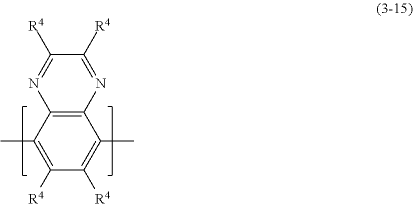

In the structural unites, each R⁴ independently represents a hydrogen atom, an alkyl group which optionally has a substituent, an alkoxy group which optionally has a substituent, an alkylthio group which optionally has a substituent, an aryl group, a heteroaryl group or a halogen atom; and each R⁵ independently represents a hydrogen atom, an alkyl group which optionally has a substituent, an aryl group or a heteroaryl group.

The definition and specific examples of the alkyl group, alkoxy group, alkylthio group, aryl group, heteroaryl group and halogen atom represented by R⁴ are the same as the foregoing definition and specific examples of the alkyl group, alkoxy group, alkylthio group, aryl group, heteroaryl group and halogen atom represented by R¹. The definition and specific examples of the alkyl group, aryl group and heteroaryl group represented by R⁵ are the same as the foregoing definition and specific examples of the alkyl group, aryl group and heteroaryl group represented by R¹.

Examples of the polymer compound including two or more second structural units include polymer compounds including a structural unit represented by formulae (4-1) to (4-15).

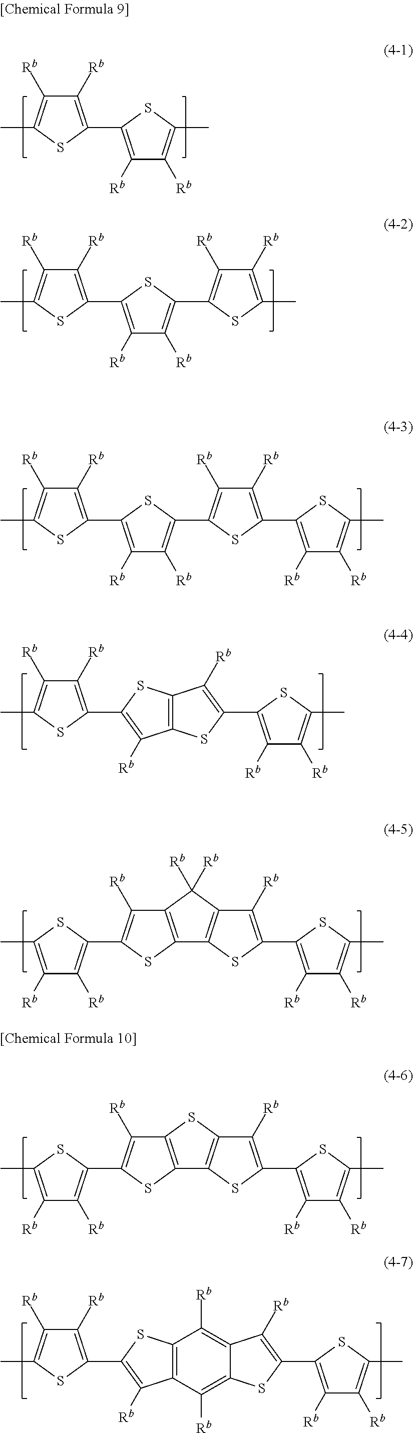

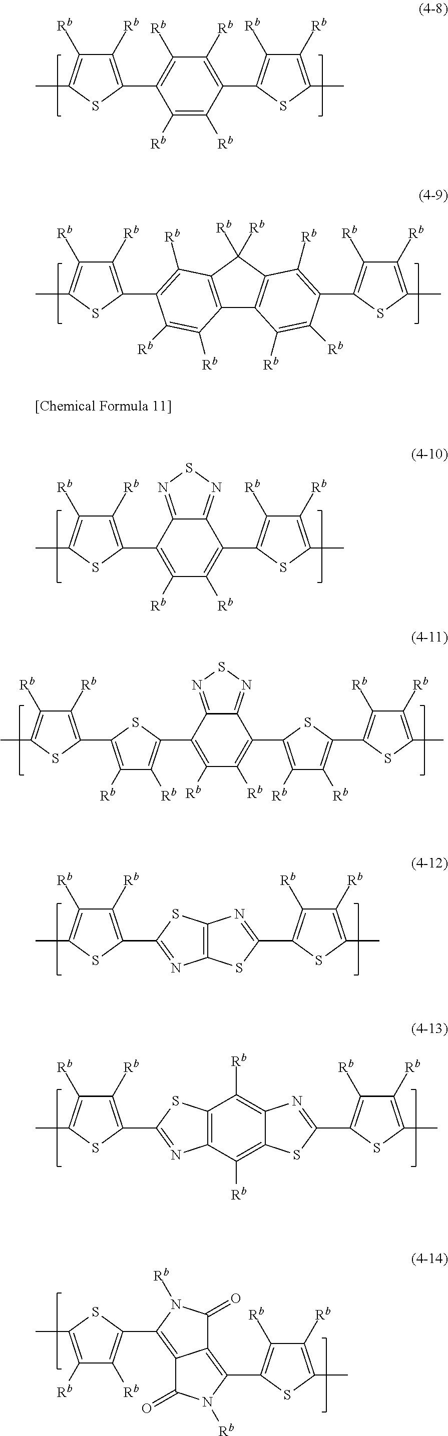

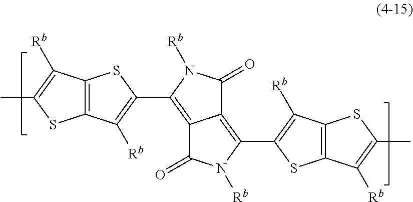

In the structural unites, each Rb independently represents a hydrogen atom, an alkyl group which optionally has a substituent, an alkoxy group which optionally has a substituent, an alkylthio group which optionally has a substituent, an aryl group, a heteroaryl group or a halogen atom.

The definition and specific examples of the alkyl group, alkoxy group, alkylthio group, aryl group and heteroaryl group represented by Rb are the same as the foregoing definition and specific examples of the alkyl group, alkoxy group, alkylthio group, aryl group and heteroaryl group represented by R¹.

Structural units in which all R¹s and R²s in the first structural unit are hydrogen atoms form a structure which is easily π-stacked. A structure which is easily π-stacked is preferable for enhancing the electric field effect mobility. However, a polymer compound composed only of structural units in which all R¹s and R²s in the first structural unit are hydrogen atoms has reduced solubility in a solvent, so that it becomes very difficult to prepare an organic thin film when an organic semiconductor is produced.

When all R¹s and R²s in the first structural unit are hydrogen atoms, it is preferable that the second structural unit contains at least one alkyl group, alkoxy group or alkylthio group so as to render the polymer compound capable of being easily dissolved in a solvent.

It is expected that a polymer compound including a structure which is easily π-stacked and a structure which enhances solubility in a solvent enables an organic thin film to be easily prepared and has high electric field effect mobility.

(Additional Structural Unit)

The polymer compound of the present invention optionally include a structural unit other than the first structural unit and the second structural unit (hereinafter sometimes referred to as an “additional structural unit”). Either only one kind or two or more kinds of additional structural units may be included in the polymer compound.

Examples of the additional structural unit include a group represented by the formula: —CR^{e}₂—, a group represented by the formula: —C(C═O)— and a group represented by the formula: —C(C═O)O—. Each R^{e} independently represents a hydrogen atom, an alkyl group which optionally has a substituent, an aryl group, a heteroaryl group or a halogen atom.

The definition and specific examples of the alkyl group, aryl group and heteroaryl group represented by W are the same as the foregoing definition and specific examples of the alkyl group, aryl group and heteroaryl group represented by R¹.

(Specific Examples of Polymer Compound)

The polymer compound of the present invention is preferably a conjugated polymer compound for enhancing the electric field effect mobility of the polymer compound.

When the polymer compound of the present invention is composed of the first structural unit, the second structural unit and an additional structural unit, the total amount of the first structural unit and the second structural unit is preferably 50% by mol or more, more preferably 70% by mol or more based on the total amount of structural units included in the polymer compound for enhancing the carrier mobility of the polymer compound.

Specific examples of the polymer compound of the present invention include polymer compounds including the first structural unit and the second structural unit and represented by the formulae (5-1) to (5-15).

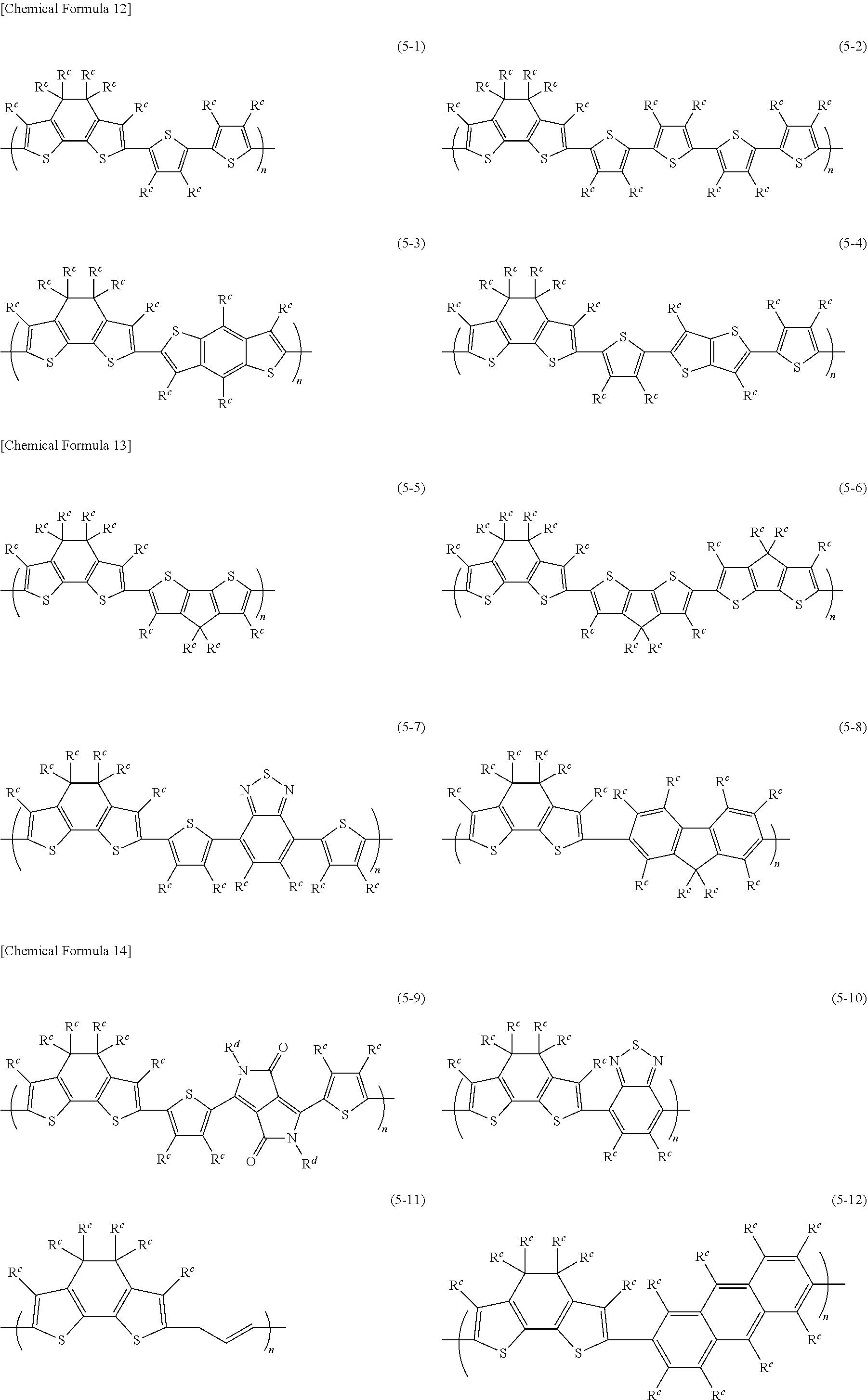

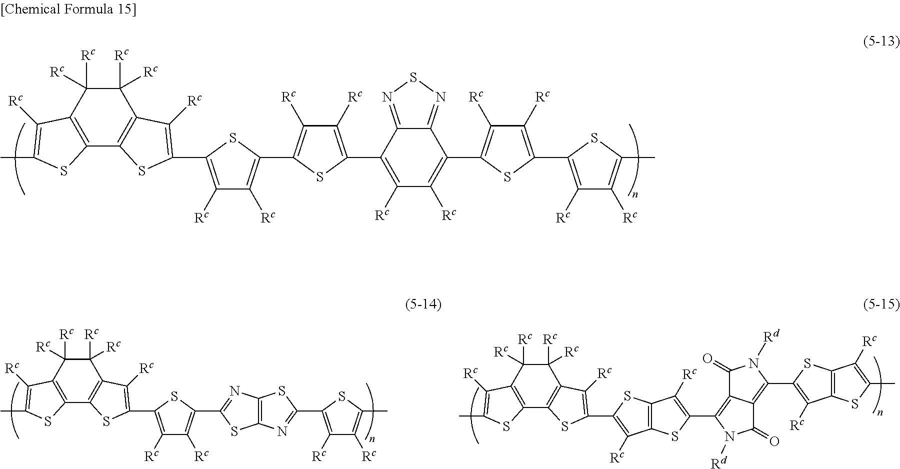

In the structural unites, each R^{C} independently represents a hydrogen atom, an alkyl group which optionally has a substituent, an alkoxy group which optionally has a substituent, an alkylthio group which optionally has a substituent, an aryl group, a heteroaryl group or a halogen atom; each R^{d} independently represents a hydrogen atom, an alkyl group which optionally has a substituent, an aryl group or a heteroaryl group; and n represents an integer of 5 or greater.

The definition and specific examples of the alkyl group, alkoxy group, alkylthio group, aryl group and heteroaryl group represented by R^{C} are the same as the foregoing definition and specific examples of the alkyl group, alkoxy group, alkylthio group, aryl group and heteroaryl group represented by R¹.

The definition and specific examples of the alkyl group, aryl group and heteroaryl group represented by R^{d} are the same as the foregoing definition and specific examples of the alkyl group, aryl group and heteroaryl group represented by R¹.

When a group active to a polymerization reaction remains at a molecular chain end in the polymer compound of the present invention, the electric field effect mobility of the polymer compound may be reduced. Therefore, the group at the molecular chain end is preferably a stable group such as an aryl group and a heteroaryl group.

The polymer compound of the present invention may be any kind of copolymer, and may be, for example, any of a block copolymer, a random copolymer, an alternating copolymer and a graft copolymer.

The polymer compound of the present invention usually has a polystyrene-equivalent number average molecular weight (Mn) of 1×10³ to 1×10⁸ as measured by gel permeation chromatography (hereinafter referred to as “GPC”).

The number average molecular weight is preferably 2×10³ or more for forming a proper thin film during preparation of a thin film.

The number average molecular weight is preferably 1×10⁶ or less for enhancing solubility in a solvent to facilitate preparation of a thin film.

(Method for Production of Polymer Compound)

The polymer compound of the present invention is produced by copolymerizing a monomer that serves as a source of the first structural unit, a monomer that serves as a source of the second structural unit, and if necessary a monomer that serves as a source of an additional structural unit.

The monomer that serves as a source of the first structural unit is, for example, a compound with an alkylmetal group attached to a bond of a structural unit represented by the formula (1). This monomer is produced by alkylmetalation of a compound represented by the formula:

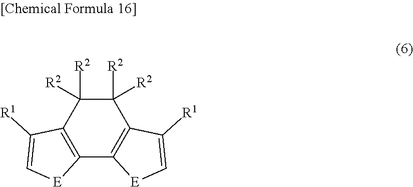

wherein R¹, R² and E have the same meanings as those described above.

Alkylmetalation of a compound represented by the formula (6) can be performed by dissolving in an appropriate solvent a compound represented by the formula (6), and reacting the solution with an alkylmetalating agent in the presence of a base. Diethyl ether, tetrahydrofuran (THF), hexane, heptane, toluene and the like can be used as the solvent. n-Butyl lithium, sec-butyl lithium, tert-butyl lithium, lithium diisopropylamide or the like can be used as the base, and trimethyltin chloride and tributyltin chloride can be used as the alkylmetalating agent.

In this case, the monomer that serves as a source of the second structural unit is a compound with a halogen atom attached to a bond of a structural unit represented by the formula (2).

The compound with a halogen atom attached to a bond of a structural unit represented by the formula (2) is produced by halogenating a compound with a hydrogen atom attached to a bond of a structural unit represented by the formula (2).

Halogenation of a compound with a hydrogen atom attached to a bond of a structural unit represented by the formula (2) may be performed by dissolving in an appropriate solvent the compound with a hydrogen atom attached to a bond of a structural unit represented by the formula (2), and reacting the solution with a halogenating agent. Chloroform, tetrahydrofuran, dimethylformamide, acetic acid and the like can be used as the solvent, and N-bromosuccinimide (NBS), bromine, N-iodosuccinimide (NIS), N-chlorosuccinimide (NCS) and the like can be used as the halogenating agent.

The monomer that serves as a source of an additional structural unit is, for example, a compound with an alkylmetal group or a halogen atom attached to a bond of a group shown as an example of the additional structural unit. Such a compound is produced by alkylmetal-converting or halogenating a compound with a hydrogen atom attached to a bond of a group shown as an example of an additional structural unit using the same method as that described above. Here, the alkylmetal group refers to a monovalent group having a structure in which an alkyl group is attached to a metal atom. Examples of the alkylmetal group include a stannyl group substituted with an alkyl group and a boryl group substituted with an alkyl group.

Subsequently, the compound with an alkylmetal group attached to a bond of a structural unit represented by the formula (1), the compound with a halogen atom attached to a bond of a structural unit represented by the formula (2), and if necessary the compound with a halogen atom or an alkylmetal group attached to a bond of a group shown as an example of an additional structural unit are dissolved in an appropriate solvent, and reacted by heating the solution in the presence of a transition metal complex and if necessary a phosphine compound.

The reaction amount of the monomer that serves as a source of the first structural unit and that of the monomer that serves as a source of the second structural unit are adjusted so that the molar ratio of the former to the latter is 30/70 to 70/30, preferably 35/65 to 65/35, more preferably 40/60 to 60/40. When the ratio of the reaction amounts of both the monomers is less than 40% by mol, molecular weight of the polymer compound may become lower, leading to a reduced electric field effect mobility.

When a monomer that serves as a source of the additional structural unit is also used during the above-mentioned reaction, the use amount thereof is 50% by mol or less, preferably 30% by mol or less based on the total amount of the monomers as described above.

An aromatic hydrocarbon solvent such as toluene and benzene; an ether solvent such as tetrahydrofuran and anisole; an aprotic polar solvent such as 1-methyl-2-pyrolidone, N,N-dimethylformamide, N,N-dimethylacetamide, and dimethyl sulfoxide, acetonitrile; etc. can be used as the solvent. Pd₂(dba)₃ (dba denotes trans, trans-dibenzylidineacetone), Pd(dba)₂, tetrakis(triphenylphosphine) palladium, palladium(II) acetate, dichlorobis(triphenylphosphine) palladium, bis(1,5-cyclooctadiene) nickel(0) and the like can be used as the transition metal complex. Tri-n-butylphosphine, tri-tert-butylphosphine, tricyclohexylphosphine, triphenylphosphine, tris-tolylphosphine (the tolyl group in the compound may be any of an ortho-tolyl group, a meta-tolyl group, and a para-tolyl group), tris(methoxyphenyl) phosphine (the methoxyphenyl group in the compound may be any of an ortho-methoxyphenyl group, a meta-methoxyphenyl group, and a para-methoxyphenyl group), (2-biphenylyl)di-tert-butylphosphine, 1,2-bis(diphenylphosphino)ethane, 1,3-bis(diphenylphosphino)propane, 1,1′-bis(diphenylphosphino)ferrocene and the like can be used as the phosphine compound. Potassium carbonate, sodium carbonate, cesium carbonate, potassium hydroxide, sodium hydroxide, lithium hydroxide, potassium acetate, sodium acetate and the like can be used as the base. The reaction temperature is adjusted to 0 to 200° C. in consideration of the stability of the compound and the reaction time. In this case, the reaction time is 30 minutes to 100 hours.

Subsequently, a purification operation such as reprecipitation, Soxhlet washing, extraction, silica gel column purification, and gel permeation chromatographic purification is performed to obtain a polymer compound of the present invention. The method for producing the polymer compound of the present invention is referred to as a first method.

The polymer compound of the present invention may also be produced by a second method which is different from the first method. In the second method, the monomer that serves as a source of the first structural unit is a compound with a halogen atom attached to a bond of a structural unit represented by the formula (1). This monomer is produced by halogenating a compound represented by the formula (6). The halogenation of the compound represented by the formula (6) can be performed substantially in the same manner as in the reaction of the halogenation of the compound with a hydrogen atom attached to a bond of a structural unit represented by the formula (2) except that a compound represented by the formula (6) is used in place of the compound with a hydrogen atom attached to a bond of a structural unit represented by the formula (2).

In this case, the monomer that serves as a source of the second structural unit is a compound in which an alkylmetal group such as a trialkylstannyl group, a dihydroxyboryl group (—B(OH)₂), or a group obtained by removing a hydroxyl group from a boric acid diester is attached to a bond of a structural unit represented by the formula (2).

The compound in which an alkylmetal group such as a trialkylstannyl group, a dihydroxyboryl group, or a group obtained by removing a hydroxyl group from a boric acid diester is attached to a bond of a structural unit represented by the formula (2) is produced by converting a structural unit represented by the formula (2) to boronic acid.

Alkylmetalation of a compound with a hydrogen atom attached to a bond of a structural unit represented by the formula (2) can be performed substantially in the same manner as in the reaction of alkylmetalation of a compound represented by the formula (6) except that the compound with a hydrogen atom attached to a bond of a structural unit represented by the formula (2) is used in place of the compound represented by the formula (6). Dihydroxyborylation or boric acid-diesterification of a compound with a hydrogen atom attached to a bond of a structural unit represented by the formula (2) may be performed by dissolving in an appropriate solvent the compound with a hydrogen atom attached to a bond of a structural unit represented by the formula (2), and reacting the solution with a trialkyl borate in the presence of a base. Diethyl ether, tetrahydrofuran (THF), hexane, heptane, toluene and the like can be used as the solvent, n-butyl lithium, sec-butyl lithium, tert-butyl lithium, lithium diisopropylamide and the like can be used as the base, and trimethyl borate, triisopropyl borate, 2-isopropoxy-4,4,5,5-tetramethyl-1,3,2-dioxaborolane and the like can be used as the trialkyl borate.

The monomer that serves as a source of the additional structural unit is, for example, a compound in which a halogen atom, an alkali metal group, a dihydroxyboryl group, or a group obtained by removing a hydroxyl group from a boric acid diester is attached to a bond of a group shown as an example of an additional structural unit. Such a compound is produced by halogenating, alkylmetalating, dihydroxyborylating or boric acid-esterifying a compound with a hydrogen atom attached to a bond of a group shown as an example of the additional structural unit using the same method as that described above.

Then, the compound with a halogen atom attached to a bond of a structural unit represented by the formula (1), a compound in which an alkali metal group, a dihydroxyboryl group, or a group obtained by removing a hydroxyl group from a boric acid diester is attached to a bond of a structural unit represented by the formula (2), and if necessary a compound in which a halogen atom, an alkali metal group, a dihydroxyboryl group, or a group obtained by removing a hydroxyl group from a boric acid diester is attached to a bond of a group shown as an example of the additional structural unit are dissolved in an appropriate solvent, and reacted by heating the solution in the presence of a transition metal complex, and if necessary a phosphine compound and a base, so that a polymer compound of the present invention is obtained.

An aromatic hydrocarbon solvent such as toluene, and benzene; an ether solvent such as tetrahydrofuran and anisole; an aprotic polar solvent such as 1-methyl-2-pyrolidone, N,N-dimethylformamide, N,N-dimethylacetamide, dimethyl sulfoxide, and acetonitrile; etc. can be used as the solvent. Pd₂(dba)₃ (dba denotes trans, trans-dibenzylidineacetone), Pd(dba)₂, tetrakis(triphenylphosphine) palladium, palladium(II) acetate, dichlorobis(triphenylphosphine) palladium, bis(1,5-cyclooctadiene) nickel(0) and the like can be used as the transition metal complex. Tri-n-butylphosphine, tri-tert-butylphosphine, tricyclohexylphosphine, triphenylphosphine, tris-tolylphosphine (the tolyl group in the compound may be any of an ortho-tolyl group, a meta-tolyl group, and a para-tolyl group), tris(methoxyphenyl) phosphine (the methoxyphenyl group in the compound may be any of an ortho-methoxyphenyl group, a meta-methoxyphenyl group, and a para-methoxyphenyl group), (2-biphenylyl)di-tert-butylphosphine, 1,2-bis(diphenylphosphino)ethane, 1,3-bis(diphenylphosphino)propane, 1,1′-bis(diphenylphosphino)ferrocene and the like can be used as the phosphine compound. Sodium carbonate, potassium carbonate, cesium carbonate, potassium hydroxide, sodium hydroxide, lithium hydroxide, potassium acetate, sodium acetate and the like can be used as the base. The reaction temperature is adjusted to 0 to 200° C. in consideration of the stability of the compound and the reaction time. In this case, the reaction time is 30 minutes to 100 hours.

Subsequently, a purification operation such as reprecipitation, Soxhlet washing, extraction, silica gel column purification, and gel permeation chromatographic purification is performed to obtain a polymer compound of the present invention.

The polymer compound of the present invention can also be produced using a compound represented by the formula (8).

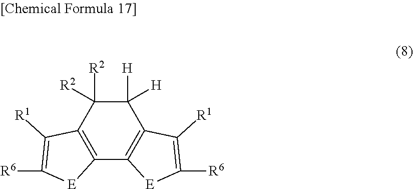

In the formula, each R⁶ independently represents a hydrogen atom, an alkyl group which optionally has a substituent, an alkoxy group which optionally has a substituent, an alkylthio group which optionally has a substituent, an aryl group, a heteroaryl group or a halogen atom; and E, R¹ and R² have the same meanings as those described above.

The definition and specific examples of the alkyl group, aryl group, heteroaryl group and halogen atom represented by R⁶ are the same as the foregoing definition and specific examples of the alkyl group, aryl group, heteroaryl group and halogen atom represented by R¹. R⁶ is preferably a hydrogen atom or a halogen atom.

The compound represented by the formula (8) can be produced by a method comprising a step of reacting a compound represented by the formula (7) with a metal hydride:

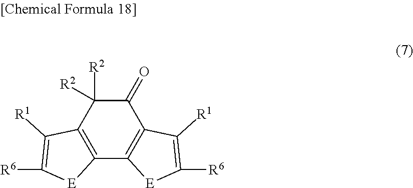

wherein E, R¹, R² and R⁶ have the same meanings as those described above.

Examples of the metal hydride to be used in the production method of the present invention include lithium aluminum hydride, sodium boron hydride, diisobutyl aluminum hydride, lithium hydride, triphenyltin hydride, tributyltin hydride, triethyltin hydride, trimethylsilane, phenylsilane, diphenylsilane, polymethyl hydroxane and trichlorosilane.

The reaction of the compound represented by the formula (7) with a metal hydride may be performed in the presence of a Lewis acid. Examples of the Lewis acid include boron trifluoride, aluminum chloride, tin(IV) chloride, silicon(IV) chloride, iron(III) chloride, titanium chloride, zinc chloride and mixtures of these acids.

The reaction of the compound represented by the formula (7) with a metal hydride may be performed in an atmosphere of an inert gas such as a nitrogen gas and an argon gas, or in the presence of a solvent. When the reaction is performed in the presence of a solvent, the reaction temperature is not particularly limited, but is preferably a temperature ranging from −80° C. to the boiling point of the solvent.

Examples of the solvent to be used for the reaction of the compound represented by the formula (7) with a metal hydride include saturated hydrocarbons such as pentane, hexane, heptane, octane, and cyclohexane; unsaturated hydrocarbons such as benzene, toluene, ethylbenzene, and xylene; and ethers such as dimethyl ether, diethyl ether, methyl-tert-butyl ether, tetrahydrofuran, tetrahydropyran, and dioxane. The solvents may be used either alone or in the form of a mixture.

After the reaction (for example, after the reaction is stopped by adding water), the product is extracted with an organic solvent and a usual post-treatment is performed, e.g. the solvent is distilled away, so that a mixture containing a compound represented by the formula (8) can be obtained. The mixture may be purified by chromatographic fractionation or by recrystallization.

<Organic Semiconductor Device>

The polymer compound of the present invention has high electric field effect mobility, and therefore can be used as an organic semiconductor material while being included in, for example, an organic layer of an organic semiconductor device. Examples of the organic semiconductor device include organic transistors, organic solar cells, and organic electroluminescence devices. The polymer compound of the present invention is useful particularly as an electric charge transport material of an organic transistor.

<Organic Semiconductor Material>

The organic semiconductor material may contain only one kind of, or two or more kinds of the polymer compound of the present invention. The organic semiconductor material may further contain a low-molecular compound or a polymer compound having carrier transportability in addition to the polymer compound of the present invention in order to enhance carrier transportability. When the organic semiconductor material contains components other than the polymer compound of the present invention, it contains the polymer compound of the present invention in an amount of preferably 30% by weight or more, more preferably 50% by weight or more. When the content of the polymer compound of the present invention is less than 30% by weight, it may be difficult to form a thin film, or proper electric charge mobility may not be obtained easily.

Examples of the compound having carrier transportability include low-molecular compounds such as arylamine derivatives, stilbene derivatives, oligothiophene and derivatives thereof, oxadiazole derivatives, and fullerenes and derivatives thereof; and polymer compounds such as polyvinyl carbazole and derivatives thereof, polyaniline and derivatives thereof, polythiophene and derivatives thereof, polypyrrole and derivatives thereof, polyphenylene vinylene and derivatives thereof, polythienylene vinylene and derivatives thereof, and polyfluorene and derivatives thereof.

The organic semiconductor material optionally contains a polymer compound material as a polymer binder in order to improve properties thereof. The polymer binder is preferably one that does not excessively reduce carrier transportability.

Examples of the polymer binder include poly(N-vinylcarbazole), polyaniline and derivatives thereof, polythiophene and derivatives thereof, poly(p-phenylene vinylene) and derivatives thereof, poly(2,5-thienylene vinylene) and derivatives thereof, polycarbonate, polyacrylate, polymethyl acrylate, polymethyl methacrylate, polystyrene, polyvinyl chloride and polysiloxane.

<Organic Transistor>

Examples of the organic transistor include those configured to include a source electrode and a drain electrode; an active layer serving as an electric current path between the electrodes and containing a polymer compound of the present invention; and a gate electrode that controls the amount of an electric current passing through the electric current path. Examples of the organic transistor configured as described above include electric field effect type organic transistors and electrostatic induction type organic transistors.

The electric field effect type organic transistor is usually an organic transistor having a source electrode and a drain electrode; an active layer serving as an electric current path between the electrodes and containing a polymer compound of the present invention; a gate electrode that controls the amount of an electric current passing through the electric current path; and an insulating layer arranged between the active layer and the gate electrode. Particularly, organic transistors are preferable in which a source electrode and a drain electrode are provided in contact with an active layer, and a gate electrode is provided so as to sandwich an insulating layer that is in contact with the active layer.

The electrostatic induction type organic transistor is usually an organic transistor having a source electrode and a drain electrode; an active layer serving as an electric current path between the electrodes and containing a polymer compound of the present invention; and a gate electrode that controls the amount of an electric current passing through the electric current path, with the gate electrode provided in the active layer. Particularly, organic transistors are preferable in which a source electrode, a drain electrode and the gate electrode are provided in contact with the active layer.

The gate electrode may have a structure capable of forming an electric current path through which an electric current passes from a source electrode to a drain electrode and of controlling the amount of an electric current passing through the electric current path by a voltage applied to the gate electrode, and examples of the gate electrode include comb-shaped electrodes.

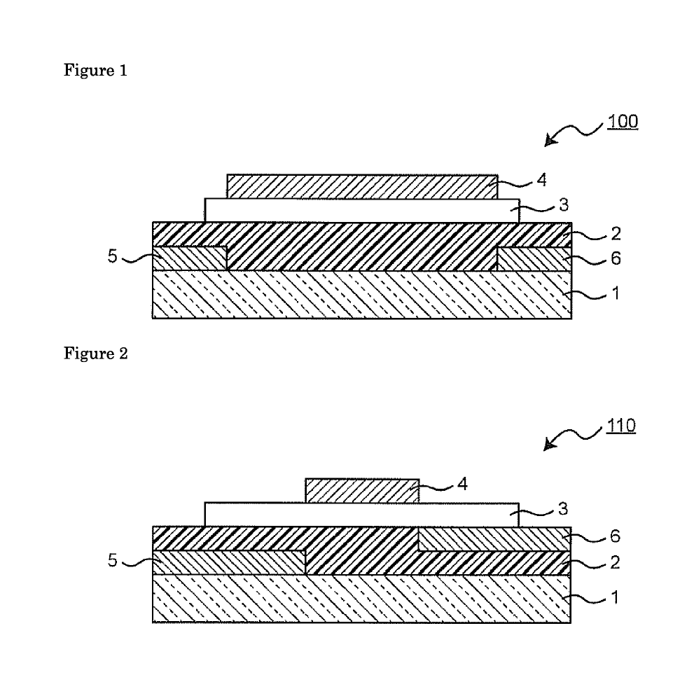

FIG. 1 is a schematic sectional view showing one example of the organic transistor (electric field effect type organic transistor) of the present invention. The organic transistor 100 shown in FIG. 1 includes a substrate 1; a source electrode 5 and a drain electrode 6 formed at a prescribed interval on the substrate 1; an active layer 2 formed on the substrate 1 so as to cover the source electrode 5 and the drain electrode 6; an insulating layer 3 formed on the active layer 2; and a gate electrode 4 formed on the insulating layer 3 so as to cover the insulating layer 3 on a region between the source electrode 5 and the drain electrode 6.

FIG. 2 is a schematic sectional view showing another example of the organic transistor (electric field effect type organic transistor) of the present invention. The organic transistor 110 shown in FIG. 2 includes a substrate 1; a source electrode 5 formed on the substrate 1; an active layer 2 formed on the substrate 1 so as to cover the source electrode 5; a drain electrode 6 formed on the active layer 2 at a prescribed interval from the source electrode 5; an insulating layer 3 formed on the active layer 2 and the drain electrode 6; and a gate electrode 4 formed on the insulating layer 3 so as to cover the insulating layer 3 on a region between the source electrode 5 and the drain electrode 6.

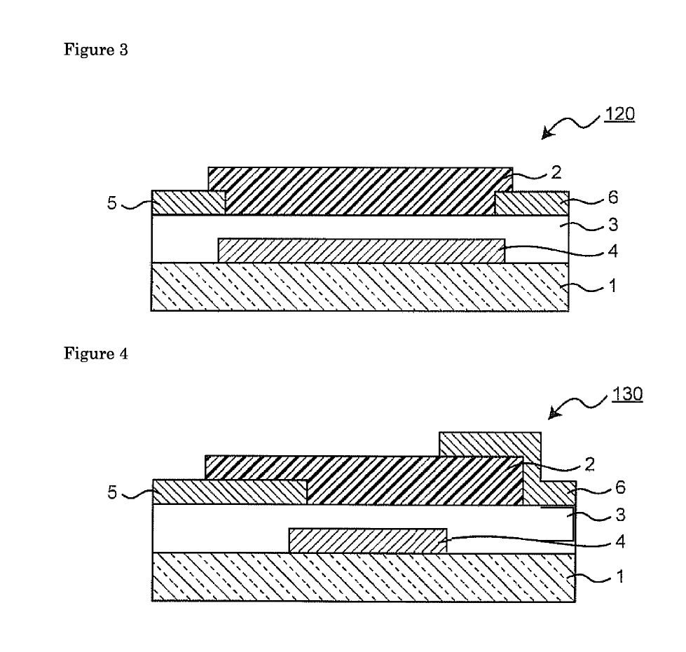

FIG. 3 is a schematic sectional view showing another example of the organic transistor (electric field effect type organic transistor) of the present invention. The organic transistor 120 shown in FIG. 3 includes a substrate 1; a gate electrode 4 formed on the substrate 1; an insulating layer 3 formed on the substrate 1 so as to cover the gate electrode 4; a source electrode 5 and a drain electrode 6 formed at a prescribed interval on the insulating layer 3 so as to partially cover a region of the insulating layer 3 under which the gate electrode 4 is formed; and an active layer 2 formed on the insulating layer 3 so as to partially cover the source electrode 5 and the drain electrode 6.

FIG. 4 is a schematic sectional view showing another example of the organic transistor (electric field effect type organic transistor) of the present invention. The organic transistor 130 shown in FIG. 4 includes a substrate 1; a gate electrode 4 formed on the substrate 1; an insulating layer 3 formed on the substrate 1 so as to cover the gate electrode 4; a source electrode 5 formed on the insulating layer 3 so as to partially cover a region of the insulating layer 3 under which the gate electrode 4 is formed; an active layer 2 formed on the insulating layer 3 so as to partially cover the source electrode 5; and a drain electrode 6 formed on the insulating layer 3 at a prescribed interval from the source electrode 5 so as to partially cover the active layer 2.

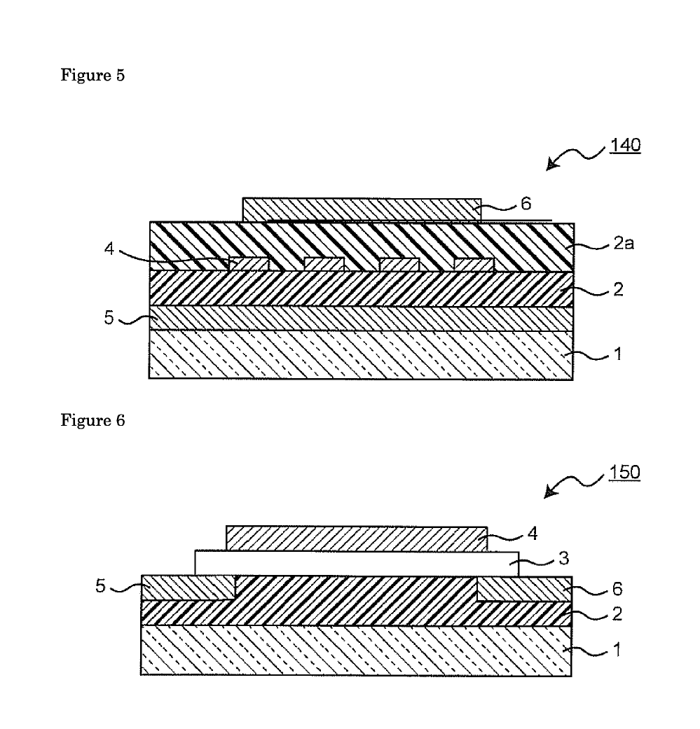

FIG. 5 is a schematic sectional view showing another example of the organic transistor (electrostatic induction type organic transistor) of the present invention. The organic transistor 140 shown in FIG. 5 includes a substrate 1; a source electrode 5 formed on the substrate 1; an active layer 2 formed on the source electrode 5; a plurality of gate electrodes 4 formed at prescribed intervals on the active layer 2; an active layer 2a formed on the active layer 2 so as to cover all the gate electrodes 4 (a material forming the active layer 2a may be either the same as or different from that of the active layer 2); and a drain electrode 6 formed on the active layer 2a.

FIG. 6 is a schematic sectional view showing another example of the organic transistor (electric field effect type organic transistor) of the present invention. The organic transistor 150 shown in FIG. 6 includes a substrate 1; an active layer 2 formed on the substrate 1; a source electrode 5 and a drain electrode 6 formed at a prescribed interval on the active layer 2; an insulating layer 3 formed on the active layer 2 so as to partially cover the source electrode 5 and the drain electrode 6; and a gate electrode 4 formed on the insulating layer 3 so as to partially cover each of a region of the insulating layer 3 under which the source electrode 5 is formed and a region of the insulating layer 3 under which the drain electrode 6 is formed.

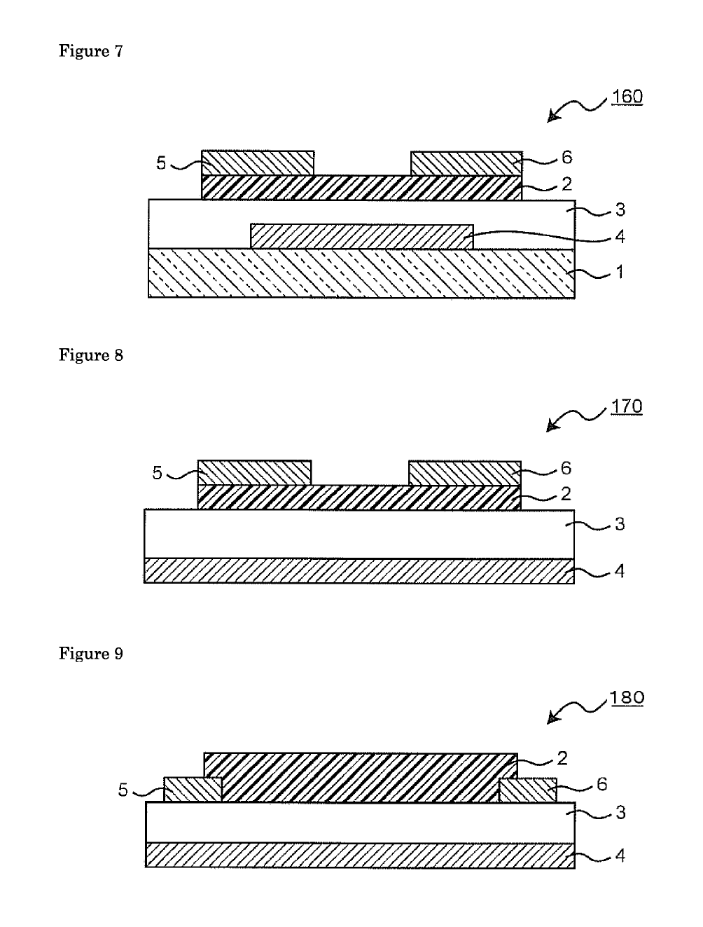

FIG. 7 is a schematic sectional view showing another example of the organic transistor (electric field effect type organic transistor) of the present invention. The organic transistor 160 shown in FIG. 7 includes a substrate 1; a gate electrode 4 formed on the substrate 1; an insulating layer 3 formed on the substrate 1 so as to cover the gate electrode 4; an active layer 2 formed so as to cover a region of the insulating layer 3 under which the gate electrode 4 is formed; a source electrode 5 formed on the active layer 2 so as to partially cover the active layer 2; and a drain electrode 6 formed on the active layer 2 at a prescribed interval from the source electrode 5 so as to partially cover the active layer 2.

FIG. 8 is a schematic sectional view showing another example of the organic transistor (electric field effect type organic transistor) of the present invention. The organic transistor 170 shown in FIG. 8 includes a gate electrode 4; an insulating layer 3 formed on the gate electrode 4; an active layer 2 formed on the insulating layer 3; and a source electrode 5 and a drain electrode 6 formed at a prescribed interval on the active layer 2. In this case, the gate electrode 4 is configured to also serve as a substrate 1.

FIG. 9 is a schematic sectional view showing another example of the organic transistor (electric field effect type organic transistor) of the present invention. The organic transistor 180 shown in FIG. 9 includes a gate electrode 4; an insulating layer 3 formed on the gate electrode 4; a source electrode 5 and a drain electrode 6 formed at a prescribed interval on the insulating layer 3; and an active layer 2 formed on the insulating layer 3 so as to partially cover the source electrode 5 and the drain electrode 6.

In the above-mentioned organic transistor of the present invention, the active layer 2 and/or the active layer 2a are composed of a film containing the polymer compound of the present invention, and form an electric current path (channel) between the source electrode 5 and the drain electrode 6. The gate electrode 4 controls the amount of an electric current passing through the electric current path (channel) by applying a voltage.

These electric field effect type organic transistors can be produced by publicly known methods, for example, the method described in Japanese Patent laid-open Publication No. H5(1993)-110069. The electrostatic induction type organic transistor can be produced by publicly known methods such as the method described in Japanese Patent laid-open Publication No. 2004-006476.

The material of the substrate 1 may be a material which does not impair the hinder properties of the organic transistor. As the substrate, a glass substrate, a flexible film substrate or a plastic substrate can be used.

The material of the insulating layer 3 may be a material having high electric insulation performance, and SiOₓ, SiNₓ, Ta₂O₅, polyimide, polyvinyl alcohol, polyvinyl phenol, organic glass, a photoresist and the like can be used, but from the viewpoint of reducing the voltage, it is preferable to use a material having a high dielectric constant.

When the active layer 2 is formed on the insulating layer 3, it is also possible to treat the surface of the insulating layer 3 with a surface treatment agent such as a silane coupling agent, followed by forming the active layer 2 in order to improve the interface properties of the insulating layer 3 and the active layer 2.

In the case of the organic electric field effect type transistor, charges such as electrons and holes generally pass through the vicinity of the interface between the insulating layer and the active layer. Therefore, the state of the interface significantly influences on the mobility of the transistor. Thus, as a method for enhancing the properties by improving the surface state, control of the interface using a silane coupling agent has been proposed (for example, Surface Chemistry, 2007, vol. 28, No. 5, pages 242-248).

Examples of the silane coupling agent include silylamine compounds such as alkylchlorosilanes (octyltrichlorosilane (OTS), octadecyltrichlorosilane (ODTS), phenylethyltrichlorosilane and the like), alkylalkoxysilanes, fluorinated alkylchlorosilanes, fluorinated alkylalkoxysilanes, and hexamethyldisilazane (HMDS). The surface of the insulating layer is optionally subjected to an ozone UV treatment or an O₂ plasma treatment before the surface is treated with a surface treatment agent.

By the above-mentioned treatment, the surface energy of a silicon oxide film or the like to be used as the insulating layer can be controlled. Such surface treatment can improve the orientation properties of a film forming the active layer on the insulating layer and affords high electric charge transportability (mobility).

For the gate electrode 4, metals such as gold, platinum, silver, copper, chromium, palladium, aluminum, indium, molybdenum, low-resistance polysilicon, and low-resistance amorphous silicon, and such materials as tin oxide, indium oxide, and indium/tin oxide (ITO) can be used. These materials may be used either alone or in combination of two or more thereof. For the gate electrode 4, a densely doped silicon substrate can also be used. The densely doped silicon substrate has both performance as a gate electrode and performance as a substrate. When the gate electrode 4 which also has performance as a substrate is used, the substrate 1 is optionally omitted in an organic transistor in which the substrate 1 and the gate electrode 4 are in contact with each other.

The source electrode 5 and the drain electrode 6 are preferably composed of a low-resistance material, especially preferably composed of gold, platinum, silver, copper, chromium, palladium, aluminum, indium, molybdenum and the like. These materials may be used either alone or in combination of two or more thereof.

In the organic transistor, a layer composed of other compounds is optionally interposed between the source electrode 5 and the drain electrode 6, and the active layer 2. Examples of the layer described above include layers composed of low-molecular compounds having electron transportability, low-molecular compounds having hole transportability, alkali metals, alkali earth metals, rare earth metals, complexes of these metals and organic compounds, halogens such as iodine, bromine, chlorine, and iodine chloride, sulfur oxide compounds such as sulfuric acid, anhydrous sulfuric acid, sulfur dioxide, and sulfuric acid salts, nitrogen oxide compounds such as nitric acid, nitrogen dioxide, and nitric acid salts, halogenated compounds such as perchloric acid and hypochlorous acid, alkylthiol compounds, and aromatic thiol compounds such as aromatic thiols and fluoridated alkyl aromatic thiols.

After the above-mentioned organic transistor is prepared, preferably, a protective film is formed on the organic transistor in order to protect a device. This allows the organic transistor to be shielded from air, so that deterioration of properties of the organic transistor can be suppressed. Further, when a display device that is to be driven is formed on the organic transistor, influences exerted on the organic transistor in a step of forming the display device can be reduced by the protective film.

Examples of the method for forming a protective film include methods of covering an organic transistor with a UV curable resin, a thermosetting resin, an inorganic SiONₓ film or the like. For effectively shielding the organic transistor from air, it is preferable to form a protective film (for example, in a dry nitrogen atmosphere, in a vacuum, or the like) after the preparation of the organic transistor, without exposing the organic transistor to air.

An organic electric field effect transistor, one type of the organic transistor formed as described above, can be applied as an active matrix drive type liquid crystal display, an image drive switching device of an organic electroluminescence display, or the like. The organic electric field effect transistor of the embodiment described above contains the polymer compound of the present invention as an active layer, and accordingly includes an active layer having improved electric charge transportability, so that its electric field effect mobility is enhanced. Therefore, the organic electric field effect transistor is useful, for example, for production of a display having a sufficient response speed.

### EXAMPLES

Examples will be shown below for describing the present invention more in detail, but the present invention is not intended to be limited to these examples.

(NMR Analysis)

NMR measurement was performed using an NMR apparatus (INOVA 300 manufactured by Varian Co., Ltd.) with a compound dissolved in deuterated chloroform or deuterated acetone.

(Mass Analysis)

Mass analysis was performed using a mass spectrometer (AccuTOF TLC JMS-T100TD manufactured by JEOL Ltd.).

(Molecular Weight Analysis)

The number average molecular weight and the weight average molecular weight of a polymer compound were determined using a gel permeation chromatograph (GPC, manufactured by Waters Corporation, trade name: Alliance GPC 2000). A polymer compound to be measured was dissolved in ortho-dichlorobenzene, and the solution was injected into the GPC. Ortho-dichlorobenzene was used for a mobile phase of the GPC. The column used was TSKgel GMHHR-H(S)HT (2 columns connected, manufactured by TOSOH CORPORATION). A UV detector was used as a detector.

### Synthesis Example 1

### Synthesis of Compound 2

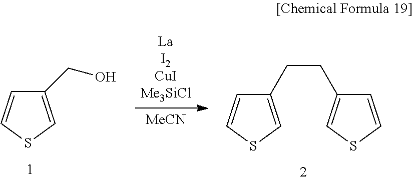 [SMILES: "MeCN" ; OCc1ccsc1 ; c1cc(CCc2ccsc2)cs1]

In a flask were put 21 g (0.18 mol) of 3-hydroxymethyl thiophene, 25 g (0.18 mol) of powdered lanthanum, 9.1 g (36 mmol) of iodine, 6.8 g (36 mmol) of copper(I) iodide, 39 g (0.36 mol) of trimethylsilyl chloride and 540 mL of acetonitrile, and refluxed and stirred for 2 hours. The reaction solution was concentrated, and poured into water, and toluene was added to extract a toluene solution containing a reaction product. The toluene solution containing a reaction product was washed with an aqueous hydrochloric acid solution, and then washed with water. Thereafter, the solvent in the toluene solution was evaporated by an evaporator. The obtained solid was purified with silica gel column chromatography using hexane as an eluting solvent, and a compound 2 isolated was dried. The compound 2 obtained weighed 5.5 g, and the yield thereof was 32%.

¹H-NMR (300 MHz, CDCl₃) 67.25 (m, 2H), 6.93 (m, 4H), 2.96 (s, 4H)

### Synthesis Example 2

### Synthesis of Compound 3

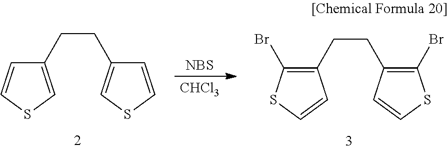

In a flask were put 5.5 g (28 mmol) of the compound 2, 10 g (57 mmol) of N-bromosuccinimide and chloroform (280 mL), and stirred at 0° C. for 5 hours. The reaction solution was added to an aqueous sodium thiosulfate solution, and chloroform was further added to extract a chloroform solution containing a reaction product. Thereafter, the chloroform solution was washed with water. The solvent in the chloroform solution was evaporated by an evaporator. The obtained solid was purified with silica gel column chromatography using hexane as an eluting solvent, and a compound 3 isolated was dried. The compound 3 obtained weighed 5.7 g, and the yield thereof was 57%.

¹H-NMR (300 MHz, CDCl₃) 67.18 (d, 2H), 6.73 (d, 2H), 2.84 (s, 4H)

### Synthesis Example 3

### Synthesis of Compound 4

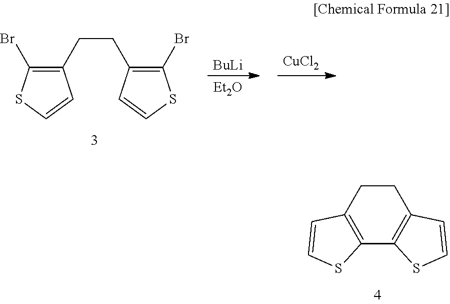

In a flask were put 4.5 g (13 mmol) of the compound 3 and 180 mL of diethyl ether, stirred, and cooled to 0° C. To the reaction solution was added dropwise 11 mL of a hexane solution containing 2.6 M n-butyl lithium. Thereafter, the reaction solution was stirred at 0° C. for 3 hours. Thereafter, to the reaction solution was added 4.3 g (32 mmol) of copper(II) chloride. Thereafter, the reaction solution was stirred at room temperature for 3 hours. The reaction solution was poured into water, and toluene was added to extract a toluene solution containing a reaction product. The toluene solution was washed with an aqueous hydrochloric acid solution, and then washed with water. Thereafter, the solvent in the toluene solution was evaporated by an evaporator. The obtained solid was purified with silica gel column chromatography using hexane as an eluting solvent, and a compound 4 isolated was dried. The compound 4 obtained weighed 1.4 g, and the yield thereof was 57%.

¹H-NMR (300 MHz, CDCl₃) 67.06 (d, 2H), 6.90 (d, 2H), 2.90 (s, 4H)

### Synthesis Example 4

### Synthesis of Compound 5

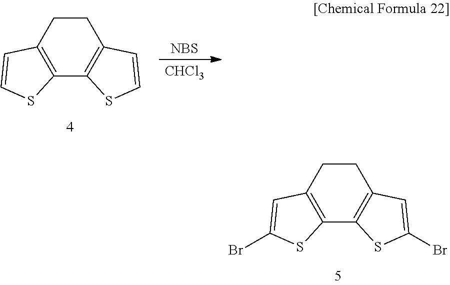

In a flask were put 1.5 g (7.5 mmol) of the compound 4, 3.0 g (17 mmol) of N-bromosuccinimide and 30 mL of chloroform, and stirred at room temperature for 2 hours. The reaction solution was added to an aqueous sodium thiosulfate solution, and chloroform was further added to extract a chloroform solution containing a reaction product. Thereafter, the chloroform solution was washed with water. Thereafter, the solvent in the chloroform solution was evaporated by an evaporator. The obtained solid was purified with silica gel column chromatography using hexane as an eluting solvent, and a compound 5 isolated was dried. The compound 5 obtained weighed 0.50 g, and the yield thereof was 19%.

MS m/z=347.90, 349.90, 351.89

### Synthesis Example 5

### Synthesis of Compound 6

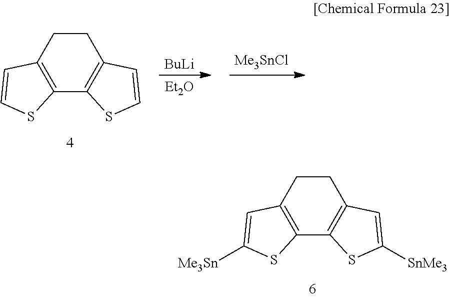

In a flask were put 1.3 g (6.8 mmol) of the compound 4 and 26 mL of diethyl ether, stirred, and cooled to 0° C. To the reaction solution was added dropwise 6.2 mL of a hexane solution containing 2.6 M n-butyl lithium. Thereafter, the reaction solution was stirred at 0° C. for 3 hours. To the reaction solution was added 3.5 g (18 mmol) of trimethyltin chloride. Thereafter, the reaction solution was stirred at room temperature for 3 hours. The reaction solution was poured into water, and hexane was added to extract a hexane solution containing a reaction product. The hexane solution was washed with an aqueous hydrochloric acid solution, and then washed with water. The solvent in the hexane solution was evaporated by an evaporator. The obtained solid was purified with silica gel column chromatography using hexane as an eluting solvent, and a compound 6 isolated was dried. The compound 6 obtained weighed 0.80 g, and the yield thereof was 23%.

¹H-NMR (300 MHz, CDCl₃) 66.98 (s, 2H), 2.90 (s, 4H), 0.37 (s, 18H)

### Example 1

### Synthesis of Polymer Compound A

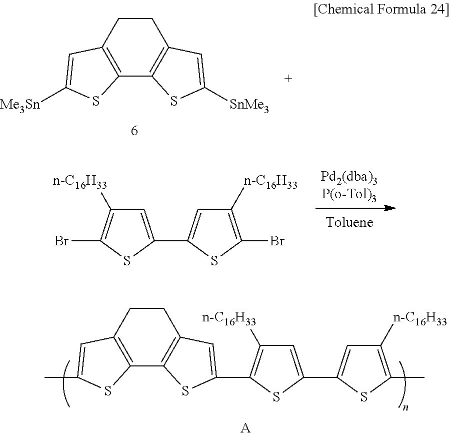

In a flask with the gas contained therein replaced by nitrogen were put 0.200 g (0.386 mmol) of the compound 6, 0.284 g (0.367 mmol) of 5,5′-dibromo-4,4′-di-n-hexadecyl-2,2′-bithiophene, 5.3 mg of tris(dibenzylideneacetone)dipalladium, 10.6 mg of tris-ortho-tolylphosphine and 28 mL of toluene, and were refluxed for 4 hours. Thereafter, to the reaction solution was added 1.0 g of bromobenzene, and the mixture was refluxed for 30 minutes. Thereafter, the reaction solution was poured into methanol. A precipitated substance was collected by filtration, and the filtered substance was washed with methanol for 4 hours and with acetone for 4 hours using a Soxhlet washer. The solid after washing was dissolved in toluene, 1.0 g of a sodium N,N-diethyldithiocarbamate trihydrate and water were added to the obtained toluene solution, and the mixture was refluxed for 3 hours. The solution after reflux was poured into methanol, and a precipitated substance was collected by filtration. The precipitated substance was dissolved in toluene, and purified by silica gel column chromatography using toluene as an eluting solvent. The obtained toluene solution was poured into methanol, and a precipitated substance was collected by filtration to obtain 0.10 g of a polymer compound A. The polymer compound A had a polystyrene-equivalent number average molecular weight of 1.9×10⁴ and a polystyrene-equivalent weight average molecular weight of 3.4×10⁴.

### Example 2

### Synthesis of Polymer Compound B

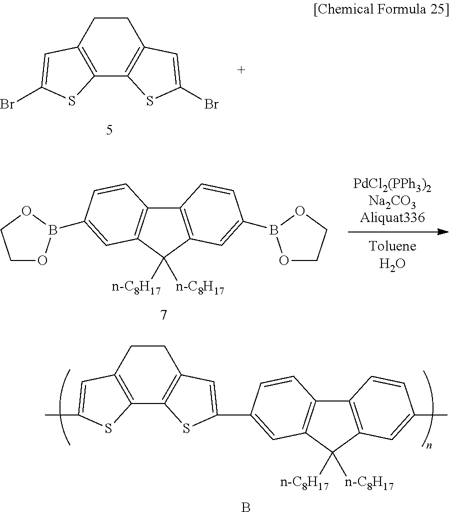

In a flask with the gas contained therein replaced by nitrogen were put 0.350 g (1.00 mmol) of the compound 5, 0.531 g (1.00 mmol) of a compound 7, 58 mL of toluene, 35 mL of dichlorobis(triphenylphosphine) palladium and 0.16 g of methyltrioctylammonium chloride, and were stirred. To this solution was added dropwise 1.5 mL of a 2 mol/L aqueous sodium carbonate solution, and the mixture was refluxed for 3 hours. To the reaction solution was added 31 mg of bromobenzene, and the mixture was refluxed for 1 hour. Next, to the reaction solution was added 1.0 g of a sodium N,N-diethyldithiocarbamate trihydrate, and the mixture was refluxed for 3 hours. Thereafter, the reaction solution was poured into water, and toluene was added to extract a toluene layer. A toluene solution was washed with an aqueous acetic acid solution and water, and the toluene solution was added dropwise to acetone to obtain a precipitated substance. The precipitated substance was dissolved in toluene, and purified by silica gel column chromatography using toluene as an eluting solvent. The toluene solution after purification was added dropwise to methanol, and a precipitated substance was filtered to obtain 0.10 g of a polymer compound B. The polymer compound B had a polystyrene-equivalent number average molecular weight of 9.8×10³ and a polystyrene-equivalent weight average molecular weight of 2.2×10⁴.

### Example 3

### Synthesis of Polymer Compound C

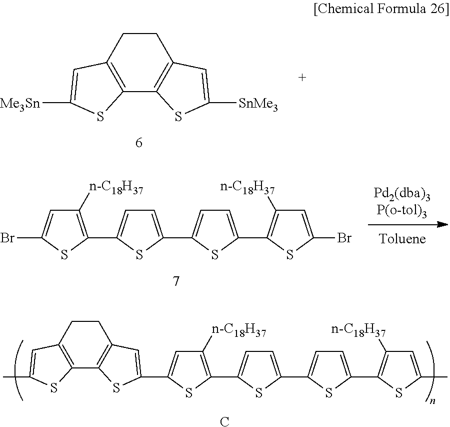

In a flask with the gas contained therein replaced by nitrogen were put 0.146 g (0.282 mmol) of the compound 6, 0.266 g (0.268 mmol) of the compound 7, 3.9 mg of tris(dibenzylideneacetone)dipalladium, 7.7 mg of tris-ortho-tolylphosphine and 50 mL of toluene, and were refluxed for 4 hours. Thereafter, to the reaction solution was added 1.0 g of bromobenzene, and the mixture was refluxed for 30 minutes. Thereafter, the reaction solution was poured into methanol. A precipitated substance was collected by filtration, and the filtered substance was washed with methanol for 4 hours and with acetone for 4 hours using a Soxhlet washer. The solid after washing was dissolved in toluene, 1.0 g of a sodium N,N-diethyldithiocarbamate trihydrate and water were added to the obtained toluene solution, and the mixture was refluxed for 3 hours. The solution after reflux was poured into methanol, and a precipitated substance was collected by filtration. The precipitated substance was dissolved in toluene, and purified by silica gel column chromatography using toluene as an eluting solvent. The obtained toluene solution was poured into methanol, and a precipitated substance was collected by filtration to obtain 0.10 g of a polymer compound C. The polymer compound C had a polystyrene-equivalent number average molecular weight of 2.0×10⁴ and a polystyrene-equivalent weight average molecular weight of 6.0×10⁴.

### Example 4

### Synthesis of Polymer Compound D

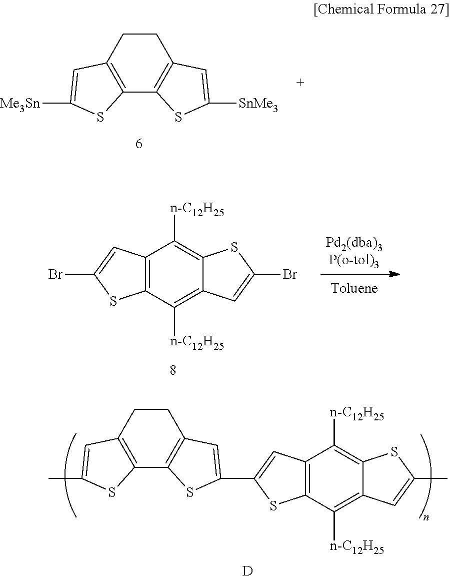

In a flask with the gas contained therein replaced by nitrogen were put 0.150 g (0.290 mmol) of the compound 6, 0.188 g (0.275 mmol) of a compound 8, 4.0 mg of tris(dibenzylideneacetone)dipalladium, 7.9 mg of tris-ortho-tolylphosphine and 50 mL of toluene, and were refluxed for 4 hours. Thereafter, to the reaction solution was added 1.0 g of bromobenzene, and the mixture was refluxed for 30 minutes. Thereafter, the reaction solution was poured into methanol. A precipitated substance was collected by filtration, and the filtered substance was washed with methanol for 4 hours and with acetone for 4 hours using a Soxhlet washer. The solid after washing was dissolved in toluene, 1.0 g of a sodium N,N-diethyldithiocarbamate trihydrate and water were added to the obtained toluene solution, and the mixture was refluxed for 3 hours. The solution after reflux was poured into methanol, and a precipitated substance was collected by filtration. The precipitated substance was dissolved in toluene, and purified by silica gel column chromatography using toluene as an eluting solvent. The obtained toluene solution was poured into methanol, and a precipitated substance was collected by filtration to obtain 0.10 g of a polymer compound D. The polymer compound D had a polystyrene-equivalent number average molecular weight of 1.6×10⁴ and a polystyrene-equivalent weight average molecular weight of 3.4×10⁴.

### Example 5

### Synthesis of Polymer Compound E

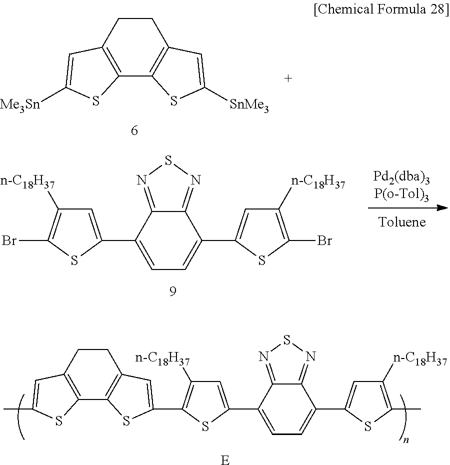

In a flask with the gas contained therein replaced by nitrogen were put 0.200 g (0.386 mmol) of the compound 6, 0.353 g (0.467 mmol) of a compound 9, 5.3 mg of tris(dibenzylideneacetone)dipalladium, 10.6 mg of tris-ortho-tolylphosphine and 50 mL of toluene, and were refluxed for 4 hours. Thereafter, to the reaction solution was added 1.0 g of bromobenzene, and the mixture was refluxed for 30 minutes. Thereafter, the reaction solution was poured into methanol. A precipitated substance was collected by filtration, and the filtered substance was washed with methanol for 4 hours and with acetone for 4 hours using a Soxhlet washer. The solid after washing was dissolved in toluene, 1.0 g of a sodium N,N-diethyldithiocarbamate trihydrate and water were added to the obtained toluene solution, and the mixture was refluxed for 3 hours. The solution after reflux was poured into methanol, and a precipitated substance was collected by filtration. The precipitated substance was dissolved in toluene, and purified by silica gel column chromatography using toluene as an eluting solvent. The obtained toluene solution was poured into methanol, and a precipitated substance was collected by filtration to obtain 0.10 g of a polymer compound E. The polymer compound E had a polystyrene-equivalent number average molecular weight of 1.6×10⁴ and a polystyrene-equivalent weight average molecular weight of 3.9×10⁴.

### Example 6

### Preparation and Evaluation of Organic Transistor 1

An organic transistor 1 having a structure shown in FIG. 9 was prepared using a solution containing the polymer compound A.

The surface of a densely doped n-type silicon substrate as a gate electrode was thermally oxidized to form a silicon oxide film (hereinafter, referred to as a “thermally oxidized film”). The thermally oxidized film functions as an insulating film. Next, a source electrode and a drain electrode were prepared on the thermally oxidized film by a photolithography process. The source electrode and the drain electrode had a chromium (Cr) layer and a gold (Au) layer in order from the thermally oxidized film side, and had a channel length of 20 μm and a channel width of 2 mm. The thus-obtained substrate on which the thermally oxidized film, source electrode and drain electrode had been formed was ultrasonically washed with acetone, and subjected to a UV ozone treatment with an ozone UV cleaner. Thereafter, the surface of the thermally oxidized film was modified with β-phenethyltrichlorosilane, and the surfaces of the source electrode and the drain electrode were modified with pentafluorobenzenethiol. Next, the surface-treated thermally oxidized film, source electrode and drain electrode were spin-coated with an ortho-dichlorobenzene solution of 0.5% by weight of the polymer compound A at a rotation speed of 1000 rpm to form an organic semiconductor layer (active layer). Thereafter, the organic semiconductor layer was heated at 170° C. for 30 minutes to produce an organic transistor 1.

The gate voltage Vg and the source-drain voltage Vsd of the obtained organic transistor 1 were changed to measure transistor properties. The electric field effect mobility was 6.5×10⁻¹ cm²/Vs.

### Example 7

### Preparation and Evaluation of Organic Transistor 2

An organic transistor 2 was prepared in the same manner as in Example 6 except that a polymer compound C was used in place of the polymer compound A.

The gate voltage Vg and the source-drain voltage Vsd of the obtained organic transistor 2 were changed to measure transistor properties. The electric field effect mobility was 7.6×10⁻³ cm²/Vs.

### Synthesis Example 6

### Synthesis of Compound 11

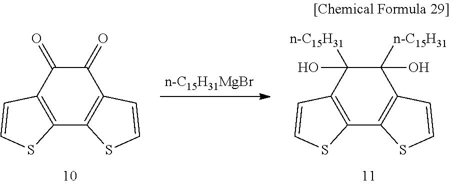

The gas in a 100 mL three-necked flask was replaced by nitrogen, 0.4 g (1.8 mmol) of a compound 10 and 5.4 mL of dry THF were added to the flask, and the mixture was heated to 80° C. Thereafter, 10.9 mL of a THF solution containing 5.4 mmol of n-pentadecylmagnesium bromide was added at 80° C., and the mixture was stirred for 2 hours. Thereafter, 10 mL of water was added to stop the reaction, and the reaction solution was extracted twice with chloroform. The obtained organic layer was washed with a saturated aqueous ammonium chloride solution twice and a saturated saline solution once, and dried with anhydrous sodium sulfate, and the solvent was distilled away under reduced pressure. The obtained residue was purified by silica gel column chromatography to obtain a compound 11. The compound 11 obtained weighed 512 mg, and the yield thereof was 34%.

¹H-NMR (300 MHz, CO(CD₃)₂): δ (ppm)=7.25 (d, 2H), 7.20 (d, 2H), 3.83 (s, 2H), 2.0-1.0 (m, 56H), 0.93 (t, 6H).

### Synthesis Example 7

### Synthesis of Compound 12

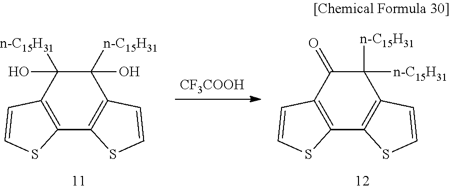

The gas in a 100 mL three-necked flask was replaced by nitrogen, 0.5 g (0.77 mmol) of the compound 11, 40 mL of acetic acid and 20 mL of trifluoroacetic acid were then added to the flask, and the mixture was heated at 80° C. for 1 hour. After completion of reaction, the reaction solution was poured into 300 mL of water, and the mixture was extracted twice with toluene. The obtained organic layer was washed with a saturated aqueous sodium hydrogen carbonate solution three times, and dried with anhydrous magnesium sulfate, and the solvent was distilled away under reduced pressure. The obtained residue was purified by silica gel column chromatography to obtain a compound 12. The compound 12 obtained weighed 451 mg, and the yield thereof was 93%. The compound 12 was further synthesized by a similar method.

¹H-NMR (300 MHz, CDCl₃): δ (ppm)=7.44 (d, 1H), 7.34 (d, 1H), 7.05 (d, 1H), 6.98 (s, 1H), 2.16 (m, 4H), 1.72 (m, 2H), 1.24 (m, 48H), 0.87 (t, 6H).

### Example 8

### Synthesis of Compound 13

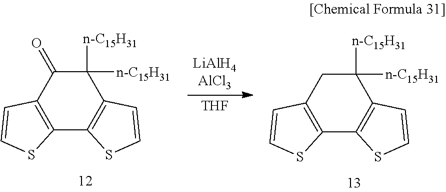

In a 500 mL flask were added 3.0 g (4.57 mmol) of the compound 12 and 150 mL of dry THF under a nitrogen atmosphere. Subsequently, 1.74 g (45.8 mmol) of lithium aluminum hydride (LiAlH₄) was added, 3.05 g (22.9 mmol) of aluminum chloride was then added little by little, and the mixture was stirred at 60° C. for 3 hours. After completion of reaction, the obtained reaction solution was slowly added dropwise to 200 ml of ice water. The obtained solution was made acidic by adding 4 N hydrochloric acid, and then extracted with toluene three times. The obtained organic layer was washed twice with a saturated saline solution, and then dried with anhydrous magnesium sulfate, and the solvent was distilled away under reduced pressure. The obtained residue was purified by silica gel column chromatography with hexane as a mobile phase to obtain a compound 13 as a yellow oil. The compound 13 obtained weighed 2.75 g, and the yield thereof was 98%.

¹H-NMR (300 MHz, CDCl₃): δ (ppm)=7.03 (d, 1H), 7.03 (d, 1H), 6.88 (d, 1H), 6.85 (d, 1H), 2.78 (brs, 2H), 1.50 (m, 4H), 1.25 (m, 20H), 0.88 (t, 6H).

### Synthesis Example 8

### Synthesis of Compound 14

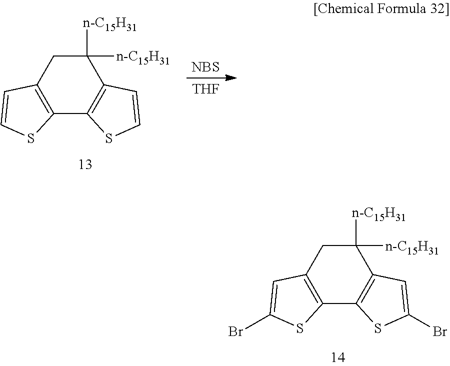

In a 500 mL flask were added 0.59 g (0.96 mmol) of the compound 13 and 100 mL of dry THF under a nitrogen atmosphere. Thereafter, 0.38 g (2.12 mmol) of N-bromosuccinimide was added, and the mixture was stirred at room temperature for 3 hours. After completion of reaction, 2 ml of a saturated aqueous sodium thiosulfate solution and 20 ml of water were added, and the mixture was extracted twice with toluene. The obtained organic layer was washed twice with a saturated saline solution, and then dried with anhydrous magnesium sulfate, and the solvent was distilled away under reduced pressure. The obtained residue was purified by silica gel column chromatography with hexane as a mobile phase, and then purified by a recycling preparative gel permeation chromatograph (JAIGEL-1H,2H manufactured by Japan Analytical Industry Co., Ltd.) to obtain a compound 14 as a light yellow solid. The compound 14 obtained weighed 0.66 g, and the yield thereof was 89%.

¹H-NMR (300 MHz, CDCl₃): δ (ppm)=6.82 (s, 1H), 6.81 (s, 1H), 2.69 (brs, 2H), 1.50 (m, 4H), 1.25 (m, 20H), 0.88 (t, 6H).

### Synthesis Example 9

### Synthesis of Compound 15

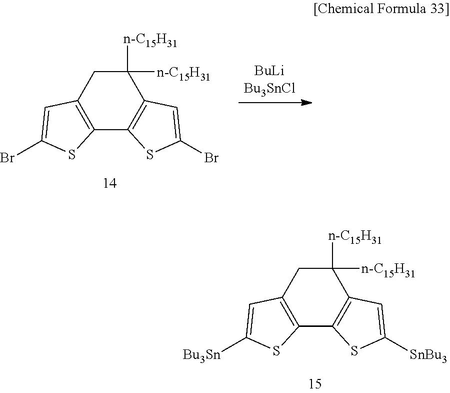

In a reaction container with the gas in a flask replaced by nitrogen were put 1.0 g (1.30 mmol) of the compound 14 and 50 mL of dehydrate THF to form a uniform solution. The solution was kept at −78° C., and 1.93 mL (5.19 mmol) of a hexane solution of 2.69 M n-butyl lithium was added dropwise to the solution over 10 minutes. After the hexane solution was added dropwise, the mixture was stirred at −78° C. for 1 hour. Thereafter, 1.69 g (5.19 mmol) of tributyltin chloride was added. After the tributyltin chloride was added, the mixture was stirred at −78° C. for 10 minutes, and then stirred at room temperature (25° C.) for 2 hours. Thereafter, 100 ml of water was added to stop the reaction, and a reaction product was extracted with hexane. The organic layer, i.e. the hexane solution, was washed with water, dried with anhydrous magnesium sulfate, and filtered, and the filtrate liquid was then concentrated with an evaporator to distill away the solvent. The obtained oily substance was purified by ODS column chromatography using a mixed solvent of acetonitrile and THF as an eluting solvent to obtain 1.14 g of a compound 15. The yield of the compound 15 was 73%.

¹H-NMR (300 MHz, CDCl₃): δ (ppm)=0.87 (m, 24H), 1.20 (m, 76H), 1.60 (m, 16H), 2.78 (s, 2H), 6.86 (s, 2H).

### Example 9

### Synthesis of Polymer Compound F

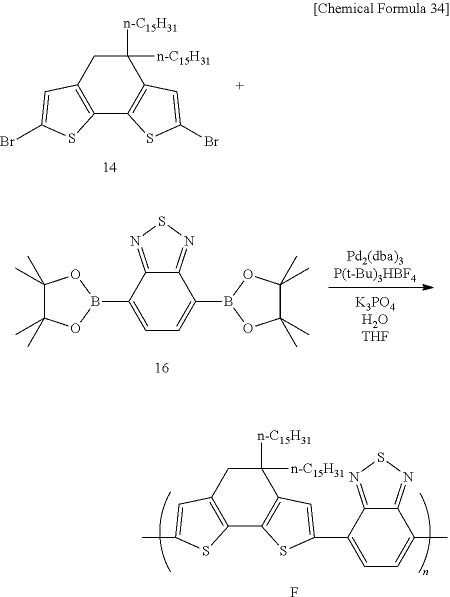

The gas in a 200 mL flask equipped with a reflux tube was replaced by nitrogen, 115.6 mg (1.50 mmol) of the compound 14 was then added, 3.8 ml of THF was then added, and the obtained mixed solution was bubbled with an argon gas for 30 minutes. Thereafter, 6.87 mg (0.7.5 μmol) of tris(dibenzylideneacetone)dipalladium(0), 4.87 mg (16 μmol) of tri-tert-butylphosphonium tetrafluoroborate, 0.75 mL of a 3 M aqueous potassium phosphate solution and 3.8 mL of a THF solution containing 58.2 mg (0.15 mmol) of a compound 16 were added, and the mixture was stirred at 80° C. for 1 hour. Thereafter, 5.1 mL of a chlorobenzene solution containing 50 mg of phenylboron boric acid was added, and the mixture was further reacted at 80° C. for 1 hour. Thereafter, 1.3 g of sodium diethyldithiocarbamate and 15 g of water were added, and the mixture was stirred under reflux for 3 hours. The obtained reaction solution was left standing, and a separated organic layer was washed with water and a 10% by weight aqueous acetic acid solution. Thereafter, the separated organic layer was added dropwise to 100 mL of acetone to obtain a precipitated substance. The obtained precipitated substance was purified by silica gel column chromatography using o-dichlorobenzene as an eluting solvent, and the obtained o-dichlorobenzene solution was then poured into methanol to precipitate a solid. The obtained solid was filtered, and dried to obtain 27 mg of a polymer compound F. The polymer compound F had a polystyrene-equivalent number average molecular weight of 3.0×10⁴ and a polystyrene-equivalent weight average molecular weight of 2.0×10⁵.

### Example 10

### Synthesis of Polymer Compound G

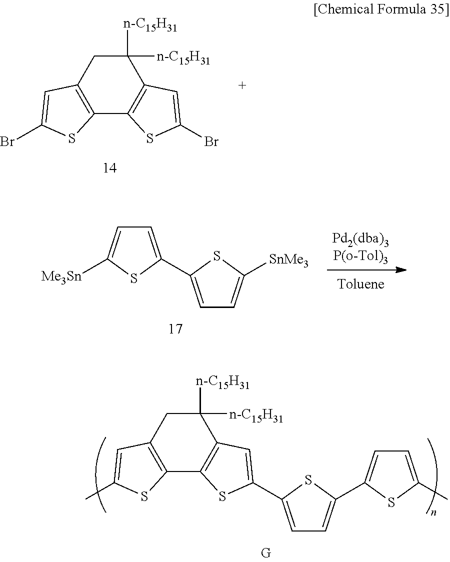

The gas in a 100 mL four-necked flask equipped with a reflux tube was replaced by nitrogen, 109.9 mg (0.143 mmol) of the compound 14, 73.8 mg (0.150 mmol) of a compound 17 and 15 mL of dry toluene were then added, and bubbled with an argon gas for 30 minutes to be degassed. Thereafter, 1.8 mg (2 μmol) of tris(dibenzylideneacetone)dipalladium(0) and 2.4 mg (8 μmol) of tris(o-toluyl)phosphine were added, and the mixture was stirred at 100° C. for 5 hours. Then, 6.2 mL of an o-dichlorobenzene solution containing 70.7 mg (0.45 mmol) of phenyl bromide was beforehand bubbled with an argon gas for 30 minutes to be degassed, the o-dichlorobenzene solution was added to the reaction solution, and the mixture was stirred at 100° C. for 1 hour. Thereafter, 0.9 g of a sodium N,N-diethyldithiocarbamate trihydrate and 7.9 g of water were added to the reaction solution, and the mixture was stirred at 100° C. for 3 hours. The obtained reaction solution was left standing, and a separated organic layer was washed with water and a 10% by weight aqueous acetic acid solution. Thereafter, the separated organic layer was added dropwise to 100 mL of acetone to obtain a precipitated substance. The obtained precipitated substance was purified by silica gel column chromatography using o-dichlorobenzene as an eluting solvent, the obtained o-dichlorobenzene solution was then poured into methanol to precipitate a solid, and the obtained solid was filtered. The obtained solid was washed with acetone for 3 hours, with methanol for 4 hours, with acetone for 4 hours and with hexane for 4 hours using a Soxhlet extractor, and dried to obtain 69 mg of a polymer compound G. The yield of the polymer compound G was 59%. The polymer compound G had a polystyrene-equivalent number average molecular weight of 2.9×10⁴ and a polystyrene-equivalent weight average molecular weight of 3.0×10⁵.

### Example 11

### Synthesis of Polymer Compound H

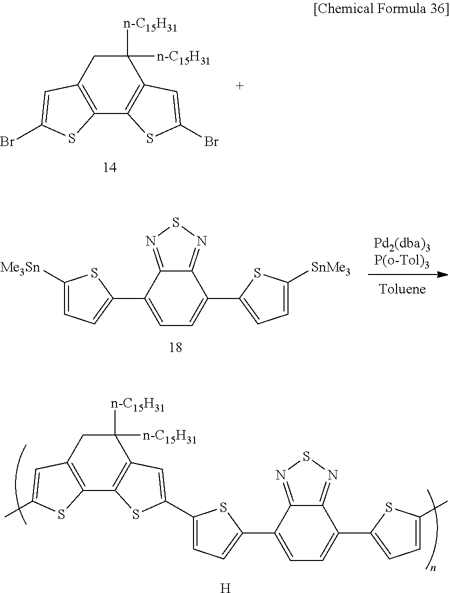

The gas in a 100 mL four-necked flask equipped with a reflux tube was replaced by nitrogen, 83.3 mg (0.108 mmol) of the compound 14, 75.1 mg (0.120 mmol) of a compound 18 and 12 mL of dry toluene were then added, and bubbled with an argon gas for 30 minutes to be degassed. Thereafter, 2.20 mg (2.4 μmol) of tris(dibenzylideneacetone)dipalladium(0) and 2.92 mg (9.6 μmol) of tris(o-toluyl)phosphine were added, and the mixture was stirred at 100° C. for 3 hours. Then, 5.0 mL of an o-dichlorobenzene solution containing 188.4 mg (1.2 mmol) of phenyl bromide was beforehand bubbled with an argon gas for 30 minutes to be degassed, the o-dichlorobenzene solution was added to the reaction solution, and the mixture was stirred at 100° C. for 1 hour. Thereafter, 0.6 g of a sodium N,N-diethyldithiocarbamate trihydrate and 5.4 g of water were added, and the mixture was stirred at 100° C. for 3 hours. The obtained reaction solution was left standing, and a separated organic layer was washed with water and a 10% by weight aqueous acetic acid solution. Thereafter, the separated organic layer was added dropwise to 80 mL of acetone to obtain a precipitated substance. The obtained precipitated substance was purified by silica gel column chromatography using o-dichlorobenzene as an eluting solvent, the obtained o-dichlorobenzene solution was then poured into 80 mL of methanol to precipitate a solid, and the obtained solid was filtered. The obtained solid was washed with acetone for 3 hours using a Soxhlet extractor, and dried to obtain 47.8 mg of a polymer compound H. The obtained polymer compound H had a polystyrene-equivalent number average molecular weight of 1.1×10⁴ and a polystyrene-equivalent weight average molecular weight of 2.4×10⁴.

### Example 12

### Synthesis of Polymer Compound I

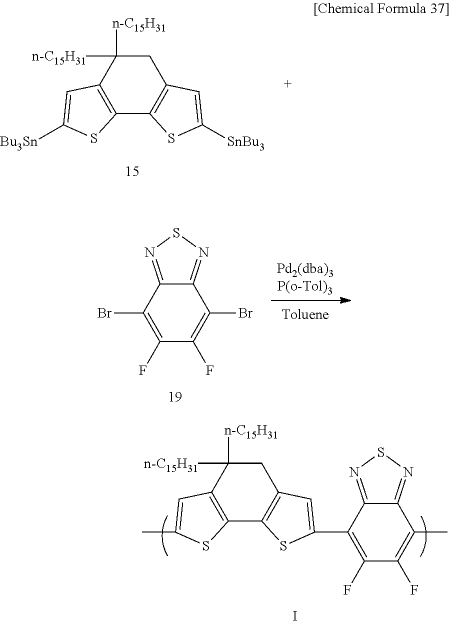

The gas in a 100 mL four-necked flask equipped with a reflux tube was replaced by nitrogen, 178.7 mg (0.15 mmol) of the compound 15, 39.6 mg (0.12 mmol) of a compound 19 and 15 mL of dry toluene were then added to the flask, and bubbled with an argon gas for 30 minutes to be degassed. Thereafter, 2.75 mg (3 μmol) of tris(dibenzylideneacetone)dipalladium(0) and 3.65 mg (12 μmol) of tris(o-toluyl)phosphine were added, and the mixture was stirred at 100° C. for 3 hours. Then, 6.2 mL of an o-dichlorobenzene solution containing 235 mg (1.5 mmol) of phenyl bromide was beforehand bubbled with an argon gas for 30 minutes to be degassed, the o-dichlorobenzene solution was added to the reaction solution, and the mixture was stirred at 100° C. for 1 hour. Thereafter, 0.8 g of a sodium N,N-diethyldithiocarbamate trihydrate and 6.8 g of water were added, and the mixture was stirred at 100° C. for 3 hours. The obtained reaction solution was left standing, and a separated organic layer was washed with water and a 10% by weight aqueous acetic acid solution. Thereafter, the separated organic layer was added dropwise to 100 mL of acetone to obtain a precipitated substance. The obtained precipitated substance was purified by silica gel column chromatography using o-dichlorobenzene as an eluting solvent, the obtained o-dichlorobenzene solution was then poured into 100 mL of methanol to precipitate a solid, and the obtained solid was filtered. The obtained solid was washed with acetone for 3 hours using a Soxhlet extractor, and dried to obtain 81 mg of a polymer compound I. The obtained polymer compound I had a polystyrene-equivalent number average molecular weight of 3.7×10⁴ and a polystyrene-equivalent weight average molecular weight of 2.2×10⁵.

### Example 13

### Preparation and Evaluation of Organic Transistor 3

An organic transistor 3 was prepared in the same manner as in Example 6 except that the polymer compound F was used in place of the polymer compound A.

The gate voltage Vg and the source-drain voltage Vsd of the obtained organic transistor 3 were changed to measure transistor properties. The electric field effect mobility was 0.13 cm²/Vs.

### Example 14

### Preparation and Evaluation of Organic Transistor 4

An organic transistor 4 was prepared in the same manner as in Example 6 except that the polymer compound G was used in place of the polymer compound A.

The gate voltage Vg and the source-drain voltage Vsd of the obtained organic transistor 4 were changed to measure transistor properties. The electric field effect mobility was 0.024 cm²/Vs.

### Example 15

### Preparation and Evaluation of Organic Transistor 5

An organic transistor 5 was prepared in the same manner as in Example 6 except that the polymer compound H was used in place of the polymer compound A.

The gate voltage Vg and the source-drain voltage Vsd of the obtained organic transistor 5 were changed to measure transistor properties. The electric field effect mobility was 0.0051 cm²/Vs.

### Example 16

### Preparation and Evaluation of Organic Transistor 6

An organic transistor 6 was prepared in the same manner as in Example 6 except that the polymer compound I was used in place of the polymer compound A.

The gate voltage Vg and the source-drain voltage Vsd of the obtained organic transistor 6 were changed to measure transistor properties. The electric field effect mobility was 0.027 cm²/Vs.

### DESCRIPTION OF THE REFERENCE NUMERALS

1: Substrate
2, 2a: Active layer
3: Insulating layer
4: Gate electrode
5: Source electrode
6: Drain electrodes
100, 110, 120, 130, 140, 150, 160, 170, 180: Organic transistor

1. A polymer compound comprising a structural unit represented by the formula: 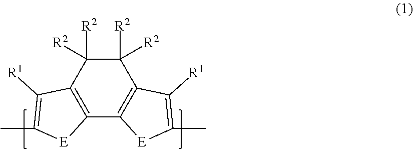
wherein each E independently represents —O—, —S— or —Se—; each R¹ independently represents a hydrogen atom, an alkyl group which optionally has a substituent, an alkoxy group which optionally has a substituent, an alkylthio group which optionally has a substituent, an aryl group, a heteroaryl group or a halogen atom; and each R² independently represents a hydrogen atom, an alkyl group which optionally has a substituent, an aryl group, a heteroaryl group or a halogen atom, or two R²s are linked to form a ring and each of the other R²s independently represents a hydrogen atom, an alkyl group which optionally has a substituent, an aryl group, a heteroaryl group or a halogen atom, and a structural unit which is different from the structural unit represented by the formula (1) and is represented by the formula:
Ar¹ (2)
wherein Ar¹ represents a divalent aromatic group, a group represented by —CR³═CR³— or a group represented by wherein each R³ independently represents a hydrogen atom, an alkyl group which optionally has a substituent, an aryl group, a heteroaryl group or a cyano group.

2. The polymer compound according to claim 1, wherein E is —S—.

3. The polymer compound according to claim 1, wherein R¹ is a hydrogen atom.

4. The polymer compound according to claim 1, wherein R² is a hydrogen atom.

5. The polymer compound according to claim 1, wherein the structural unit represented by the formula (2) is a structural unit represented by the formulae (3-1) to (3-8): 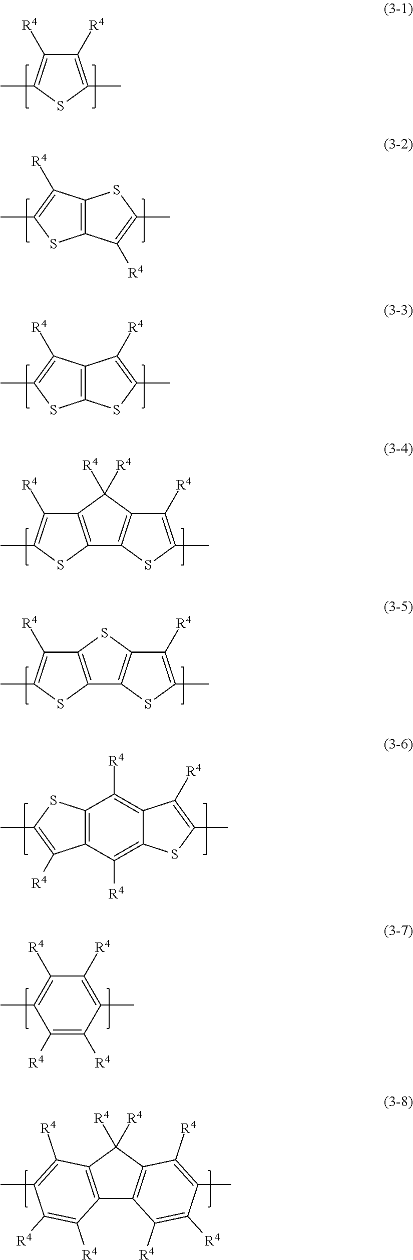
wherein each R⁴ independently represents a hydrogen atom, an alkyl group which optionally has a substituent, an alkoxy group which optionally has a substituent, an alkylthio group which optionally has a substituent, an aryl group, a heteroaryl group or a halogen atom.

6. The polymer compound according to claim 1, wherein the polymer compound is a conjugated polymer compound.

7. An organic semiconductor material comprising the polymer compound according to claim 1.

8. An organic semiconductor device comprising an organic layer including the organic semiconductor material according to claim 7.

9. An organic transistor comprising a source electrode, a drain electrode, a gate electrode and an active layer, and including the organic semiconductor material according to claim 7 in the active layer.

10. A method for producing a compound represented by the formula (8), wherein the method comprises a step of reacting a compound represented by the formula (7) with a metal hydride: 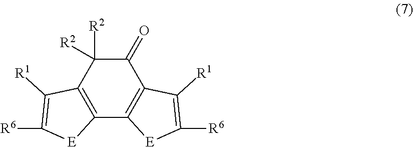
wherein each E independently represents —O—, —S— or —Se—; each R¹ independently represents a hydrogen atom, an alkyl group which optionally has a substituent, an alkoxy group which optionally has a substituent, an alkylthio group which optionally has a substituent, an aryl group, a heteroaryl group or a halogen atom; each R² independently represents a hydrogen atom, an alkyl group which optionally has a substituent, an aryl group, a heteroaryl group or a halogen atom, or two R²s are linked to form a ring and each of the other R²s independently represents a hydrogen atom, an alkyl group which optionally has a substituent, an aryl group, a heteroaryl group or a halogen atom; and each R⁶ independently represents a hydrogen atom, an alkyl group which optionally has a substituent, an alkoxy group which optionally has a substituent, an alkylthio group which optionally has a substituent, an aryl group, a heteroaryl group or a halogen atom; 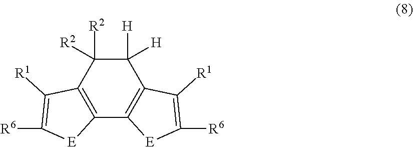
wherein E, R¹, R² and R⁶ have the same meanings as those described above.
